(19) United States
(12) Patent Application Publication
(10) Pub. No.: US 2025/0340984 A1
(43) Pub. Date: Nov. 6, 2025

(54) NONCONFORMAL OXIDE FILM DEPOSITION USING CARBON-CONTAINING INHIBITOR

(71) Applicant: Lam Research Corporation, Fremont, CA (US)

(72) Inventors: Ravi KUMAR, Beaverton, OR (US); Pulkit AGARWAL, Beaverton, OR (US); Jennifer Leigh PETRAGLIA, Portland, OR (US)

(21) Appl. No.: 18/854,240

(22) PCT Filed: Apr. 6, 2023
(86) PCT No.: PCT/US2023/065458

§ 371 Date: Oct. 4, 2024

Related U.S. Application Data
(60) Provisional application No. 63/363,376, filed on Apr. 21, 2022.
(60) Provisional application No. 63/363,377, filed on Apr. 21, 2022.

(51) Int. Cl. C23C 16/455; C23C 16/04; C23C 16/40; C23C 16/505; C23C 16/52

(52) U.S. Cl. CPC C23C 16/45536; C23C 16/045; C23C 16/402; C23C 16/45534; C23C 16/45553; C23C 16/505; C23C 16/52

(57) ABSTRACT

Examples are disclosed that relate to using a carbon-containing inhibitor to grow an oxide film nonconformally on a substrate. One example comprises performing a plurality of oxide film deposition cycles, at least one oxide film deposition cycle of the plurality of oxide film deposition cycles comprising exposing the substrate to an oxide-film precursor to adsorb oxide-film precursor to the substrate, exposing the substrate to an oxygen-containing gas, reacting the oxide-film precursor and the oxygen-containing gas, and exposing the substrate to a carbon-containing inhibitor.

### BACKGROUND

Electronic device fabrication processes may involve many steps of material deposition, patterning, and removal to form integrated circuits on substrates. Various methods can be used to deposit films of materials onto a substrate. As an example, atomic layer deposition (ALD) forms a film using one or more deposition cycles. In an ALD deposition cycle, an oxide-film precursor gas is adsorbed onto a surface of a substrate disposed in a process chamber. Excess oxide-film precursor is purged from the chamber, and the adsorbed oxide-film precursor is chemically converted into a film on the substrate, for example by oxidation to form an oxide film. A highly conformal film of a target thickness can be grown via one or more deposition cycles.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

Examples are disclosed that relate to using a carbon-containing inhibitor to grow an oxide film nonconformally in a gap. One example provides a method of forming an oxide film on a substrate, the method comprising performing a plurality of oxide film deposition cycles, at least one oxide film deposition cycle of the plurality of oxide film deposition cycles comprising exposing the substrate to an oxide-film precursor to adsorb oxide-film precursor to the substrate, exposing the substrate to an oxygen-containing gas, reacting the oxide-film precursor and the oxygen-containing gas, and exposing the substrate to a carbon-containing inhibitor. c

In some such examples, the method comprises an atomic layer deposition process.

In some such examples, additionally or alternatively a subsequent oxide film deposition cycle of the plurality of oxide film deposition cycles that is performed after the at least one oxide film deposition cycle omits exposing the substrate to the carbon-containing inhibitor.

In some such examples, reacting the oxide-film precursor and the oxygen-containing gas additionally or alternatively comprises forming a plasma comprising the oxygen-containing gas.

In some such examples, the method additionally or alternatively comprises reacting the plasma with oxidizable carbon-containing species from a prior oxide film deposition cycle of the plurality of oxide film deposition cycles.

In some such examples, the substrate additionally or alternatively comprises alternating layers of a first material and a second material, wherein a gap is formed in the alternating layers of materials and wherein the oxide film is deposited in the gap.

In some such examples, the gap additionally or alternatively comprises an aspect ratio within a range of 40:1 to 100:1.

In some such examples, the gap additionally or alternatively comprises a reentrant structure.

In some such examples, the carbon-containing inhibitor additionally or alternatively comprises one or more of an alkane, an alkene, an alkyne, a cyclic hydrocarbon, an aromatic, an alcohol, a diol, an aldehyde, an ester, an ether, a ketone, an alkyl halide, an alkyl amine, or an alkyl diamine.

In some such examples, the oxide film comprises a silicon oxide film.

Another example provides a processing tool. The processing tool comprises a process chamber, a radiofrequency power source, one or more gas inlets into the process chamber, and flow control hardware configured to control gas flow through the one or more gas inlets. The processing tool further comprises a controller operatively coupled to the flow control hardware and the radiofrequency power source. The controller is configured to fill a gap in a substrate disposed within the process chamber. The controller is configured to operate the flow control hardware to introduce an oxide-film precursor into the process chamber. The controller is further configured to operate the flow control hardware to introduce an oxygen-containing gas into the process chamber. The controller is further configured to operate the radiofrequency power source to form a plasma comprising the oxygen-containing gas. The controller is further configured to operate the flow control hardware to introduce a carbon-containing inhibitor into the process chamber after operating the radiofrequency power source to extinguish the plasma.

In some such examples, the controller is further configured to operate the flow control hardware to purge the process chamber after the controller operates the radiofrequency power source to extinguish the plasma.

In some such examples, the processing tool additionally or alternatively comprises a carbon-containing inhibitor source.

In some such examples, the carbon-containing inhibitor source additionally or alternatively comprises one or more of an alkane, an alkene, an alkyne, a cyclic hydrocarbon, an aromatic, an alcohol, a diol, an aldehyde, an ester, an ether, a ketone, an alkyl halide, an alkyl amine, or an alkyl diamine.

In some such examples, the controller is additionally or alternatively configured to operate the flow control hardware and the radiofrequency power source to perform a plurality of oxide film deposition cycles, at least some of the oxide film deposition cycles omitting operating the flow control hardware to introduce the carbon-containing inhibitor.

In some such examples, the controller is additionally or alternatively configured to control the processing tool to fill a reentrant gap in the substrate.

In some such examples, the processing tool additionally or alternatively comprises a substrate heater operatively coupled to the controller, and wherein the controller is configured to control heating of the substrate heater to a temperature within a range of 25° C. to 75° C.

Another example provides a computer-readable storage device comprising instructions executable by a computing device comprising a processor to control a substrate processing tool to fill a gap in a substrate. The instructions are executable to operate flow control hardware of the substrate processing tool to introduce an oxide-film precursor into a process chamber, thereby exposing the gap to the oxide-film precursor. The instructions are further executable to operate the flow control hardware to introduce an oxygen-containing gas into the process chamber. The instructions are further executable to operate a radiofrequency power source to form a plasma comprising the oxygen-containing gas. The instructions are further executable to operate the flow control hardware to introduce a carbon-containing inhibitor into the process chamber after extinguishing the plasma, thereby exposing the gap to the carbon-containing inhibitor.

In some such examples, the instructions executable to operate the flow control hardware to introduce the carbon-containing inhibitor into the process chamber are executable to control introduction of one or more of an alkane, an alkene, an alkyne, a cyclic hydrocarbon, an aromatic, an alcohol, a diol, an aldehyde, an ester, an ether, a ketone, an alkyl halide, an alkyl amine, or an alkyl diamine into the process chamber.

In some such examples, the instructions are additionally or alternatively executable to perform an oxide film deposition cycle that omits introducing the carbon-containing inhibitor into the process chamber.

Examples also are disclosed that relate to using a carbon-containing inhibitor to grow an oxide film nonconformally. One example provides a method of forming an oxide film. The method comprises performing at least one oxide film deposition cycle. An oxide film deposition cycle of the at least one oxide film deposition cycle comprises exposing a substrate disposed within a process chamber to an oxide-film precursor, introducing an oxygen-containing gas into the process chamber, reacting the oxide-film precursor with the oxygen-containing gas, and exposing the substrate to a carbon-containing inhibitor.

In some such examples, the method comprises an atomic layer deposition process.

In some such examples, the method additionally or alternatively comprises purging residual oxide-film precursor from the process chamber before reacting the oxide-film precursor and the oxygen-containing gas.

In some such examples, reacting the oxide-film precursor and the oxygen-containing gas additionally or alternatively comprises forming a plasma comprising the oxygen-containing gas.

In some such examples, the method additionally or alternatively comprises purging the process chamber after extinguishing the plasma and before introducing the carbon-containing inhibitor.

In some such examples, the carbon-containing inhibitor comprises an alkane.

In some such examples, the alkane comprises one or more of methane, ethane, propane, butane, pentane, or hexane.

In some such examples, the carbon-containing inhibitor additionally or alternatively comprises one or more of an alkene, an alkyne, a cyclic hydrocarbon, an aromatic, an alcohol, a diol, an aldehyde, an ester, an ether, a ketone, an alkyl halide, an alkyl amine, or an alkyl diamine.

In some such examples, the method additionally or alternatively comprises performing a plurality of oxide film deposition cycles, wherein a subsequent oxide film deposition cycle of the plurality of oxide film deposition cycles omits introducing the carbon-containing inhibitor into the process chamber.

Another example provides a processing tool comprising a process chamber, a substrate support positioned in the process chamber, a radiofrequency power source, one or more gas inlets into the process chamber, and flow control hardware configured to control gas flow through the one or more gas inlets. The processing tool further comprises a controller operatively coupled to the flow control hardware and the radiofrequency power source. The controller is configured to operate the flow control hardware to introduce an oxide-film precursor into the process chamber. The controller is further configured to operate the flow control hardware to introduce an oxygen-containing gas into the process chamber. The controller is further configured to operate the radiofrequency power source to form a plasma comprising the oxygen-containing gas. The controller is further configured to operate the flow control hardware to introduce a carbon-containing inhibitor into the process chamber after operating the radiofrequency power source to extinguish the plasma.

In some such examples, the controller is further configured to operate the flow control hardware to purge the process chamber after operating the radiofrequency power source to extinguish the plasma.

In some such examples, the processing tool additionally or alternatively comprises a carbon-containing inhibitor source.

In some such examples, the carbon-containing inhibitor source additionally or alternatively comprises one or more of methane, ethane, propane, butane, pentane, or hexane.

In some such examples, the carbon-containing inhibitor source additionally or alternatively comprises one or more of an alkene, an alkyne, a cyclic hydrocarbon, an aromatic, an alcohol, a diol, an aldehyde, an ester, an ether, a ketone, an alkyl halide, an alkyl amine, or an alkyl diamine.

In some such examples, the controller additionally or alternatively is configured to operate the flow control hardware and the radiofrequency power source to perform a plurality of oxide film deposition cycles, at least some of the oxide film deposition cycles omitting introduction of the carbon-containing inhibitor.

In some such examples, the processing tool additionally or alternatively comprises a substrate heater operatively coupled to the controller, and the controller is configured to control heating of the substrate heater to a temperature within a range of 25° C. to 75° C.

Another example provides a computer-readable storage device comprising instructions executable by a computing device comprising a processor. The instructions are executable to control a processing tool to operate flow control hardware of a substrate processing tool to introduce an oxide-film precursor into a process chamber. The instructions are further executable to operate the flow control hardware to introduce an oxygen-containing gas into the process chamber. The instructions are further executable to operate a radiofrequency power source to form a plasma comprising the oxygen-containing gas. The instructions are further executable to operate the flow control hardware to introduce a carbon-containing inhibitor into the process chamber after operating the radiofrequency power source to extinguish the plasma.

In some such examples, the instructions executable to operate the flow control hardware to introduce the carbon-containing inhibitor into the process chamber are executable to control introduction of one or more of an alkane, an alkene, an alkyne, a cyclic hydrocarbon, an aromatic, an alcohol, a diol, an aldehyde, an ester, an ether, a ketone, an alkyl halide, an alkyl amine, or an alkyl diamine into the process chamber.

In some such examples, the instructions additionally or alternatively are executable to perform an oxide film deposition cycle that omits introducing the carbon-containing inhibitor into the process chamber.

In some such examples, the instructions additionally or alternatively are executable to control the flow control hardware to purge the process chamber after operating the radiofrequency power source to extinguish the plasma.

### BRIEF DESCRIPTION OF THE DRAWINGS

FIG. 1 shows a block diagram of an example processing tool.

FIG. 2 shows a flow diagram depicting an example method for performing a deposition process.

FIG. 3 shows a flow diagram depicting an example method for performing a deposition process cycle that omits introduction of a carbon-containing inhibitor.

FIG. 4 shows a flow diagram depicting an example method for performing a deposition process cycle that comprises introduction of a carbon-containing inhibitor.

FIGS. 5A-5B schematically show example substrate structures comprising gaps.

FIGS. 6A-6B schematically show an example gap fill process using different exposures of a carbon-containing inhibitor.

FIG. 7 schematically shows an example gap fill processes for filling a high aspect ratio gap.

FIG. 8 shows a flow diagram depicting an example method for filling a gap in a substrate.

FIG. 9 schematically shows examples of nonconformal growth of an oxide film as a function of varying times of exposure to a carbon-containing inhibitor in a deposition cycle.

FIG. 10 schematically shows examples of nonconformal growth of an oxide film as a function of varying proportions of carbon and non-carbon deposition cycles.

FIGS. 11A-11B schematically show an example fabrication of spacers on a substrate.

FIG. 12 shows a flow diagram illustrating an example method for performing nonconformal oxide film deposition using a carbon-containing inhibitor.

FIG. 13 schematically shows an example computing device.

### DETAILED DESCRIPTION

The term “alcohol” represents hydrocarbon compounds comprising general formula R—OH, where R is an aryl or aliphatic group. Alcohols may have more than one OH group (polyols), such as diols, which have two OH functional groups. Example alcohols comprise methanol, ethanol, and propanol.

The term “aldehyde” represents hydrocarbon compounds comprising a terminal carbonyl group. Aldehydes have the general formula R—CHO where R is an aryl or aliphatic group. Example aldehydes comprise formaldehyde and acetaldehyde.

The term “aliphatic” represents organic compounds lacking aromatic groups.

The term “alkane” represents compounds comprising a general formula CₙH₂ₙ₊₂ and substituted linear alkanes. Example alkanes include methane, ethane, propane, and butane. Example alkanes that may be suitable for use as a carbon-containing inhibitor may comprise a general formula CₙH₂ₙ₊₂ in which n=1 to 10.

The term “alkene” represents hydrocarbon compounds comprising at least one carbon-carbon double bond. Alkanes comprising one carbon-carbon double bond have a general formula of CₙH₂ₙ. Example alkenes include ethylene, propylene, and butylenes. Alkenes may have more than one carbon-carbon double bond, such as dienes, allenes, and cumulenes. Example alkenes that may be suitable for use as a carbon-containing inhibitor may comprise a general formula CₙH₂ₙ in which n=2 to 10.

The term “alkyl amine” represents hydrocarbon compounds comprising a nitrogen with 1 to 3 alkyl substituents and 0 to 2H substituents. Alkyl amines comprise primary, secondary, tertiary, and cyclic amines. Examples of alkyl amines include methylamine, dimethylamine, trimethylamine, and piperidine.

The term “alkyl halide” represents hydrocarbon compounds comprising a halogen. Examples of alkyl halides comprise ethyl fluoride (fluoroethane), isopropyl bromide (2-bromopropane), and t-butyl chloride (2-chloro-2-methylpropane). Alkyl halides may have two or more halogen groups, such as 1,2-dichlorobutane.

The term “alkyne” represents hydrocarbon compounds comprising at least one carbon-carbon triple bond. Alkynes comprising one carbon-carbon triple bond have a general formula of CₙH₂ₙ₊₂. Alkynes may have more than one carbon-carbon triple bond, such as diynes, which have two carbon-carbon triple bonds. Example alkynes that may be suitable for use as a carbon-containing inhibitor may comprise a general formula CₙH₂ₙ₊₂ in which n=2 to 10.

The term “aromatic” represents a planar cyclic compound comprising pi bonding in resonance. The term “aromatic” comprises homocyclic compounds in which all atoms in a ring structure are carbon, and also heterocyclics in which one or more atoms in a ring structure are elements other than carbon (e.g. nitrogen).

The term “aspect ratio” represents a ratio between a depth of a feature such as a substrate gap and an average width of the feature.

The term “atomic layer deposition” (ALD) represents a process in which a film is formed on a substrate in one or more individual layers by sequentially adsorbing a precursor conformally to the substrate and reacting the adsorbed precursor to form a film layer. Examples of ALD processes comprise plasma-enhanced ALD (PEALD) and thermal ALD (TALD). PEALD and TALD respectively utilize a plasma of a reactive gas and heat to facilitate a chemical conversion of a precursor adsorbed to a substrate to a film on the substrate. The terms “growth” and “deposition”, and variants thereof, also may be used to refer to film formation.

The term “carbon-containing inhibitor” represents a carbon-containing compound that can be introduced into a process chamber in gas phase, that deposits nonconformally on a substrate surface, and that can be oxidized by an oxygen-containing gas to form gas-phase products. The carbon-containing inhibitor may inhibit growth of an oxide film by consuming oxygen, thereby leaving less oxygen for reacting with oxide-film precursors. Example carbon-containing inhibitors may comprise various alkanes, alkenes, alkynes, cyclic hydrocarbons, aromatics, alcohols, aldehydes, esters, ethers, ketones, aldehydes, alkyl halides, alkyl amines, and alkyl diamines.

The term “cyclic hydrocarbon” represents saturated and unsaturated hydrocarbon molecules comprising a closed ring structure. Example cyclic hydrocarbons include cyclopropane and cyclobutene.

The term “ether” represents hydrocarbon compounds comprising the general formula R—O—R′ where R and R′ are independently an aryl or aliphatic group. Example ethers comprise diethyl ether, methyl phenyl ether, and cyclic ethers such as furan.

The term “ester” represents hydrocarbon compounds comprising the general formula R—C(O) OR′ where R and R′ are independently any aryl or aliphatic group and wherein R may alternatively comprise H (e.g., formate). Examples esters comprise ethyl formate, methyl acetate, and ethyl acetate.

The term “gap” represents a recessed feature in a substrate surface.

The term “gap fill” represents a process that fills a gap on a substrate with a material.

The term “intermediate structure” represents a structure formed by earlier processing steps that is modified in later processing steps.

The term “ketone” represents hydrocarbon compounds comprising a non-terminal carbonyl. Ketones have the general formula R—C(O)—R′ where R and R′ are independently an aryl or aliphatic group. Example ketones comprise acetone and methyl ethyl ketone.

The term “mandrel” represents an intermediate structure in a patterning process that defines locations of spacers, and that is removed from the substrate to produce the spacers. Mandrels may comprise any suitable material, such as polysilicon, amorphous silicon, silicon oxides, silicon nitrides, or amorphous carbon.

The term “oxide film” represents a film deposited on a substrate surface that comprises oxygen and an oxidized species. Examples of oxide films comprise films of doped or undoped silicon oxide films (e.g., silicon dioxide (SiO₂), silicon oxynitride (SiOₓN_{y}, 0≤x≤2, 0≤y≤1.33), silicon oxycarbide (SiCₓO_{2-y}, 0≤x≤1, y=2x)), and metal oxides (e.g., hafnium oxide (HfOₓ), titanium oxide (TiOₓ), tungsten oxide (WOₓ), tin oxide (SnOₓ), and molybdenum oxide (MoOₓ)).

The term “oxide film deposition cycle” represents a sequence of processes used to form a layer of an oxide film. As described below, some oxide film deposition cycles may comprise the deposition of a carbon-containing inhibitor, and/or may comprise the oxidation of a carbon-containing inhibitor deposited in a prior cycle, to cause nonconformal growth.

The term “oxygen-containing gas” represents a gas species containing oxygen available for reacting with an oxide-film precursor to form an oxide film. Examples of oxygen-containing gases comprise molecular oxygen (O₂), water vapor (H₂O) and ozone (O₃).

The term “oxide-film precursor” represents any material that can be introduced into a process chamber to form an oxide film on a substrate disposed within the process chamber. Examples of oxide-film precursors include silicon-containing precursors that can be used to form silicon-containing films such as silicon dioxide, silicon oxynitride, and silicon oxycarbide films. Other examples of oxide-film precursors include metal-containing precursors for forming metal oxide films. Examples of such metal-containing precursors include hafnium-containing precursors, titanium-containing precursors, tungsten-containing precursors, tin-containing precursors, and molybdenum-containing precursors, which respectively may be used to form hafnium oxide (HfOₓ), titanium oxide (TiOₓ), tungsten oxide (WOₓ), tin oxide (SnOₓ), and molybdenum oxide (MoOₓ) films.

The term “silicon-containing precursor” represents any material that can be introduced into a process chamber in a gas phase to form a silicon-containing oxide film on the substrate. Example oxide-film precursors for forming silicon-containing films using PEALD may comprise materials having the general structure:

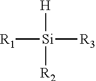

where R₁, R₂ and R₃ may be the same or different substituents, and may include silanes, siloxy groups, amines, halides, hydrogen, or organic groups, such as alkylamines, alkoxy, alkyl, alkenyl, alkynyl, and aromatic groups.

Example silicon-containing precursors include polysilanes (H₃Si—(SiH₂)ₙ—SiH₃), where n≥1, such as silane, disilane, trisilane, tetrasilane, and trisilylamine.

In some examples, the silicon-containing precursor is an alkoxysilane. Alkoxysilanes that may be used include the following:
Hₓ—Si—(OR)_{y}, where x=1-3, x+y=4 and each R is a substituted or unsubstituted alkyl, alkenyl, alkynyl or aromatic group; and
Hₓ(RO)_{y}, —Si—Si—(OR)_{y}Hₓ, is a substituted or unsubstituted alkyl, alkenyl, alkynyl or aromatic group.

Examples of silicon-containing precursors include tetraethyl orthosilicate (TEOS), tetramethoxysilane (TMOS), methylsilane, trimethylsilane (3MS), ethylsilane, butasilanes, pentasilanes, octasilanes, heptasilane, hexasilane, cyclobutasilane, cycloheptasilane, cyclohexasilane, cyclooctasilane, cyclopentasilane, 1,4-dioxa-2,3,5,6-tetrasilacyclohexane, diethoxymethylsilane (DEMS), diethoxysilane (DES), dimethoxymethylsilane, dimethoxysilane (DMOS), methyl-diethoxysilane (MDES), methyl-dimethoxysilane (MDMS), t-butoxydisilane, triethoxysilane (TES), and trimethoxysilane (TMS or TriMOS).

In some examples, the silicon-containing precursor may be a siloxane. Example siloxanes include octamethylcyclotetrasiloxane (OMCTS), octamethoxydodecasiloxane (OMODDS), tetramethylcyclotetrasiloxane (TMCTS), triethoxysiloxane (TRIES), and tetraoxymethylcyclotetrasiloxane (TOMCTS).

As noted above, in some examples, the silicon-containing precursor may be an aminosilane, such as bisdiethylaminosilane, diisopropylaminosilane, bis(t-butylamino) silane (BTBAS), di-sec-butylaminosilane, or tris(dimethylamino) silane (3DMAS). Aminosilane precursors may have the general formula: Hₓ—Si—(NR)_{y}, where x=1-3, x+y=4, and R is a substituted or unsubstituted alkyl, alkenyl, alkynyl or aromatic group or hydride group.

In some examples, a halogen-containing silane may be used such that the silane includes at least one hydrogen atom. Such a silane may have a chemical formula of SiXₐH_{y} where X is a halogen and y≥1. Dichlorosilane (H₂SiCl₂) may be used in some examples.

An example precursor for providing nitrogen for formation of a silicon oxynitride film is N₂O.

Example hafnium-containing precursors for forming hafnium oxide films (HfOₓ) include hafnium tetrachloride (HfCl₄), tetrakis(diethylamino) hafnium (Hf(N(C₂H₅)₂)₄), and tetrakis(tert-butoxide) hafnium (Hf(OC(CH₃)₃)₄).

Examples of titanium-containing precursors for forming titanium oxide films (TiOₓ) include titanium tetrachloride (TCl₄) and titanium isopropoxide (Ti(OCH(CH₃)₂)₄).

Examples of tungsten-containing precursors for forming tungsten oxide films (WOₓ) include tungsten hexafluoride (WF₆), tungsten hexachloride (WCl₆), and tungsten hexacarbonyl (W(CO)₆).

Examples of tin-containing precursors for forming tin oxide films (SnOₓ) include tin tetrachloride (SnCl₄), tetramethyltin ((CH₃)₄Sn), tetraethyltin ((C₂H₅)₄Sn), dimethyltin dichloride ((CH₃)₂SnCl₂), dibutyl (dimethoxy) stannane (Bu₂Sn(OMe)₂), tetrakis(dimethylamido)tin(IV) (Sn(NMe₂)₄), dimethylamino dimethyl tin (Me₂Sn(NMe₂)₂), and dimethylamino trimethyl tin (Me₃Sn(NMe₂)).

Examples of molybdenum-containing precursors for forming molybdenum oxide films (MoOₓ) include molybdenum pentachloride (MoCl₅), molybdenum dioxide dichloride (MoO₂Cl₂), molybdenum oxytetrachloride (MoOCl₄), and molybdenum hexacarbonyl (Mo(CO)₆).

The term “process chamber” represents an enclosure in which chemical and/or physical processes are performed on substrates. The pressure, temperature and atmospheric composition within a process chamber may be controllable to perform chemical and/or physical processes.

The term “processing tool” represents a machine comprising a process chamber and other hardware configured to enable processing to be carried out in a process chamber.

The terms “purge” and variants thereof represent processes in which unwanted species are removed from a process chamber.

The term “sticking coefficient” represents a ratio of a number of gas-phase species that impinge upon a substrate surface compared to a number of the gas-phase species that adsorb to the substrate surface.

The term “substrate” represents any object on which a film can be deposited. A substrate may represent a monolithic material or a structure comprising two or more materials, e.g., a multi-layer stack.

The term “substrate support” represents any structure for supporting a substrate in a process chamber. Examples comprise chucks, pedestals, and showerhead pedestals used for backside deposition processes.

The term “3D NAND” is an abbreviation of three-dimensional NOT AND, and represents memory architecture based upon NOT AND logic gates.

The term “3D DRAM” is an abbreviation of three-dimensional dynamic random access memory.

As mentioned above, atomic layer deposition (ALD) involves performing one or more deposition cycles to grow a thin film, such as an oxide film, on a substrate surface. ALD is often used in the fabrication of devices on semiconductor substrates. In contrast, chemical vapor deposition (CVD) processes, which are also often used in the fabrication of devices, form films in a continual growth process, rather than in a layer-by-layer growth process.

Plasma-enhanced ALD (PEALD) utilizes a plasma to facilitate the deposition of a film. For example, PEALD can be used to grow an oxide film. During a PEALD oxide film deposition cycle, an oxide-film precursor gas is introduced into a process chamber and adsorbs onto a substrate. Next, the process chamber is purged to remove excess oxide-film precursor. Then, an oxygen-containing reactant gas is introduced to the process chamber. The reactant gas may comprise an oxygen-containing gas (e.g., oxygen, ozone, or steam). A plasma then is formed, for example, by application of radiofrequency power to electrodes within the process chamber. The plasma forms reactive oxygen species, which react with the oxide-film precursor to form a layer of the oxide film. Examples of oxide films that may be formed by PEALD include films of silicon oxynitride (SiOₓN_{y}), silicon dioxide (SiO₂), silicon oxycarbide SiCₓO_{2-y}, hafnium oxide (HfOₓ), titanium oxide (TiOₓ), tungsten oxide (WOₓ), tin oxide (SnOₓ), and molybdenum oxide (MoOₓ). The growth rate of the oxide film may be on the order of 0.10-0.16 nm per cycle in some examples. As such, PEALD processing can involve tens to hundreds of deposition cycles, depending upon a desired film thickness.

PEALD may be used to grow an oxide film conformally. However, conformal growth may not be desired in some applications, as described in more detail below. Accordingly, examples are disclosed that relate to using a carbon-containing inhibitor in a deposition process to provide controllable nonconformal growth of an oxide film. While described in the context of a PEALD process, the disclosed examples also may be used in other ALD processes (e.g., TALD). Further a carbon-containing inhibitor as disclosed herein also may be used in suitable CVD processes to selectively inhibit CVD film growth.

In a PEALD process, one or more deposition cycles may be performed to form an oxide film on a substrate. In each deposition cycle, an oxide-film precursor gas is introduced into a process chamber to adsorb conformally to a substrate surface. The process chamber is purged, and an oxygen-containing gas is introduced into the process chamber. A radiofrequency power source is used to form a radiofrequency plasma comprising the oxygen-containing gas. Reactive oxygen-containing species formed in the plasma can react with adsorbed oxide-film precursor to form an oxide film.

A TALD process may similarly comprise one or more deposition cycles. In TALD, chemical reactions are enabled by relatively higher temperatures of a substrate heater within a process chamber. In each deposition cycle, an oxide-film precursor is adsorbed conformally to a substrate surface. The process chamber is purged, and an oxygen-containing gas is introduced into the process chamber. The oxygen-containing gas reacts with the oxide-film precursor due to the elevated temperature of the substrate. In contrast, thermal CVD may be employed to form a film via a continual growth process. In such a process, gases may be continuously introduced and reacted to form an oxide film on the substrate surface rather than pulsed into the process chamber.

One example of a process in which nonconformal ALD film deposition may be desired is an oxide gap fill process. In such a process, a gap on a substrate is filled with an oxide material. In ALD oxide gap fill, oxide-film precursor gas diffuses into a gap and adsorbs onto surfaces within the gap. The adsorbed gas is reacted with an oxygen-containing gas to form a film on the surfaces within the gap. This process can be repeated to progressively fill the gap. However, some gaps may have reentrant features, which are features that block a direct line of sight from a location below the reentrant feature to the gap surface in a direction normal to a substrate surface plane. Conformal film growth in a gap with a reentrant feature may cause the gap to close off at the reentrant feature before a deeper region of the gap is filled. This can leave an unfilled void within the gap, which may affect the properties of the gap. Further, gaps with high aspect ratios, such as channel holes formed in a 3D NAND memory fabrication process also may experience faster ALD film growth rates closer to an opening of the gap rather than deeper within the gap, and thus also may experience voids when locations within the gap closer to the gap opening close off before locations farther from the gap opening are completely filled.

Thus, as described in more detail below, in at least some deposition cycles during an oxide gap fill process, a carbon-containing inhibitor is introduced to the process chamber. The carbon-containing inhibitor can be introduced with the oxide-film precursor or can be introduced separately. The carbon-containing inhibitor adsorbs nonconformally on the surface of the substrate, such that a greater amount of the carbon-containing inhibitor deposits within the gap at locations closer to an opening of the gap than farther from the gap opening. Without wishing to be bound by theory, the use of a carbon-containing inhibitor in an oxide film deposition cycle may preferentially inhibit growth of the oxide film by reacting with the oxygen-containing gas used in an oxide deposition process to form gas-phase products. As the oxygen-containing gas is at least partially consumed by the carbon-containing inhibitor, the oxygen-containing gas is less available for reacting with adsorbed oxide-film precursor. Thus, oxide film growth may be inhibited to different degrees at different locations on a surface based upon quantities of carbon-containing inhibitor adsorbed to the different locations. In some examples, nonconformal adsorption of the carbon-containing inhibitor may be dependent on processing conditions such as pressure, partial pressure of the carbon-containing inhibitor, partial pressure of other gases, and/or plasma conditions. For example, the use of a capacitively coupled plasma or inductively coupled plasma may lead to directionality of ion bombardment on a substrate surface. Thus, such conditions may be controlled to help achieve nonconformal adsorption. The carbon-containing inhibitor may chemisorb and/or physisorb to the substrate surface in various examples. Further, the carbon-containing inhibitor may be converted to other species, such as elemental carbon, on the substrate surface by the processing environment.

Where a greater quantity of carbon-containing inhibitor is adsorbed to surfaces within a gap that are closer to the gap opening compared to surfaces deeper within the gap, film growth on the surfaces closer to the gap opening may be more strongly inhibited by the carbon-containing inhibitor than on the surfaces deeper within the gap. This may allow the oxide to fill the lower portions of the gap without pinching off at locations closer to the gap opening, thereby avoiding the formation of voids. Example gap fill processes are disclosed in more detail below.

In addition to gapfill applications, oxide films also can be used to form spacers in patterning applications. One example process is self-aligned double patterning (SADP). In such a process, mandrels are formed on a surface of a substrate, e.g., by lithographic patterning of a carbon film (e.g., spin-on carbon). Next, an oxide film is grown over the mandrels. A “core pull” then is performed via dry etching to remove the layer of oxide on a top surface of the mandrels, followed by ashing to remove the mandrels. In this step, oxide on the substrate surface between the mandrels is also removed by the dry etching. The portions of the oxide film on the sidewalls of the mandrels remain. These portions form the spacers once the mandrels are removed. However, the top surfaces of the spacers may become tapered during the dry etching, which may impact transfer etch performance. Thus, a carbon-containing inhibitor may be used to grow a nonconformal film as disclosed herein. Such a film may be thinner on the mandrel tops and between mandrels than on mandrel sides. This may allow a shorter dry etch process to be used. A shorter dry etch process may help to prevent or mitigate tapering of the spacers by reducing a sputtering effect at the top corners of the spacers.

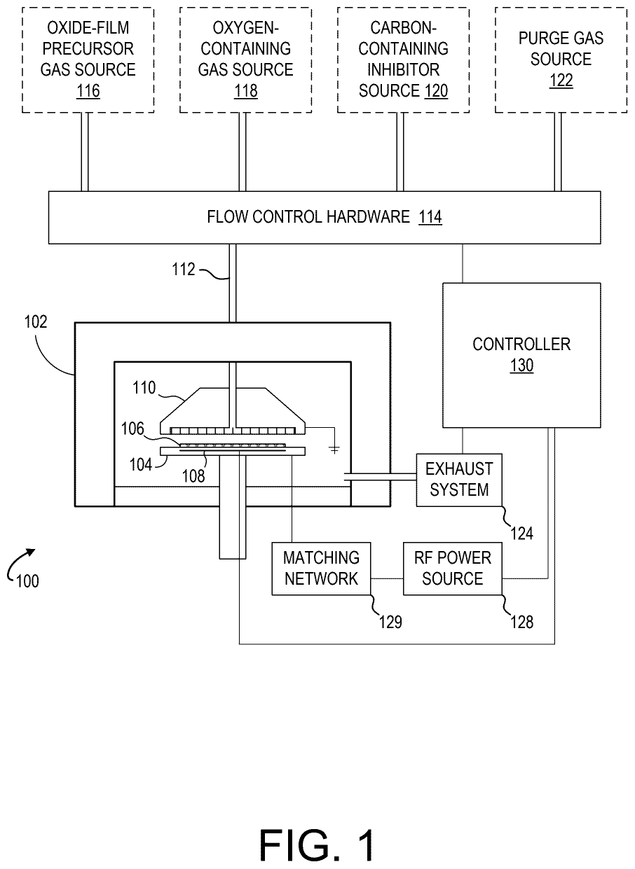

FIG. 1 shows a schematic view of an example processing tool 100 for performing atomic layer deposition using a carbon-containing inhibitor. Processing tool 100 is configured as a PEALD tool. However, as mentioned above, the use of a carbon-containing inhibitor as disclosed herein also may be used to vary the conformality of a film deposited in other types of tools. Examples may include TALD and/or other ALD tools. Examples also may include various CVD tools.

Processing tool 100 comprises a process chamber 102 and a substrate support 104 within the process chamber. Substrate support 104 is configured to support a substrate 106 disposed within process chamber 102. Substrate support 104 may comprise a pedestal, a chuck, or any other suitable structure. Process chamber 102 further may include a substrate heater 108. In other examples, a heater may be omitted, or may be located elsewhere within process chamber 102.

Processing tool 100 further comprises a showerhead 110, a gas inlet 112, and flow control hardware 114. In other examples, a processing tool may comprise a nozzle or other apparatus for introducing gas into process chamber 102, as opposed to or in addition to a showerhead. Flow control hardware 114 is connected to an oxide-film precursor gas source 116, an oxygen-containing gas source 118, a carbon-containing inhibitor source 120, and a purge gas source 122. Oxide-film precursor gas source 116 may comprise any suitable oxide-film precursor that, when reacted with the oxygen-containing gas, forms an oxide film. Example silicon-containing oxide films include silicon dioxide, silicon oxynitride, and silicon oxycarbide. Example metal oxide films include hafnium oxide, titanium oxide, tungsten oxide, tin oxide, and molybdenum oxide. Example oxide-film precursors for silicon-containing oxide films may include polysilanes, aminosilanes, halosilanes, and organosilanes. HfCl₄, Hf(N(C₂H₅)₂)₄, Hf(OC(CH₃)₃)₄, TCl₄, Ti(OCH(CH₃)₂)₄, WF₆, WCl₆, W(CO)₆, SnCl₄, (CH₃)₄Sn, (C₂H₅)₄Sn, (CH₃)₂SnCl₂, Bu₂Sn(OMe)₂, Sn(NMe₂)₄, Me₂Sn(NMe₂)₂, Me₃Sn(NMe₂), MoCl₅, MoO₂Cl₂, MoOCl₄, and Mo(CO)₆. Oxygen-containing gas source 118 may comprise, for example, O₂, O₃, water vapor, a nitrogen oxide (e.g. N₂O), H₂O₂, or a mixture of two or more thereof.

Carbon-containing inhibitor source 120 comprises any suitable carbon-containing inhibitor that can be oxidized by an oxygen-containing gas to form gas-phase products, and that adsorbs nonconformally to a substrate surface. Example carbon-containing inhibitors suitable for use for nonconformal film deposition may comprise various alkanes, alkenes, alkynes, cyclic hydrocarbons, aromatics, alcohols, aldehydes, esters, ethers, ketones, aldehydes, alkyl halides, alkyl amines, and alkyl diamines. Example carbon-containing inhibitors are described in more detail below.

Purge gas source 122 may comprise any suitable inert gas, such as argon or nitrogen. In some examples, one or more additional purge gas sources may be included, each providing a different purge gas.

Flow control hardware 114 may be controlled to flow gas from gas sources 116, 118, 120, 122 into process chamber 102 via gas inlet 112. Flow control hardware 114 may comprise one or more valves controllable to place a selected gas source in fluid connection with gas inlet 112. For example, in a first configuration, flow control hardware 114 may place oxide-film precursor gas source 116 in fluid connection with gas inlet 112 such that the oxide-film precursor flows into process chamber 102. In a second configuration, flow control hardware 114 may place oxygen-containing gas source 118 in fluid connection with gas inlet 112 to allow the oxygen-containing gas to flow into process chamber 102. In a third configuration, flow control hardware 114 may place carbon-containing inhibitor source 120 in fluid connection with gas inlet 112 to allow the carbon-containing inhibitor to flow into process chamber 102. In a fourth configuration, flow control hardware 114 may place purge gas source 122 in fluid connection with gas inlet 112 to allow the purge gas to flow into process chamber 102. In yet further configurations, flow control hardware 114 may place two or more of such gas sources in fluid communication with gas inlet 112.

Processing tool 100 further comprises an exhaust system 124. Exhaust system 124 is configured to receive gas outflowing from process chamber 102. In some examples, exhaust system 124 is configured to actively remove gas from process chamber 102 and/or apply a partial vacuum. Exhaust system 124 may comprise any suitable hardware, including one or pumps.

Processing tool 100 further comprises a radiofrequency power source 128 that is electrically connected to substrate support 104. Radiofrequency power source 128 is configured to form a plasma comprising the oxygen-containing gas. Showerhead 110 is configured as a grounded opposing electrode in this example. In other examples, radiofrequency power source 128 may supply radiofrequency power to showerhead 110, or to other suitable electrode structure. Processing tool 100 may include a matching network 129 for impedance matching of the radiofrequency power source 128. Radiofrequency power source 128 may be configured for any suitable frequency and power. Examples of suitable frequencies include 400 kHz and 13.56 MHz. Examples of suitable powers include powers between 0 and 7000 watts. In some examples, radiofrequency power source 128 is configured to operate at a plurality of different frequencies and/or powers.

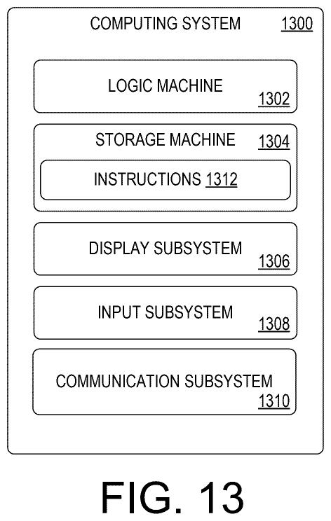

Controller 130 is operatively coupled to substrate heater 108, flow control hardware 114, exhaust system 124, and radiofrequency power source 128. Controller 130 is configured to control various functions of processing tool 100 to perform a thin film deposition process, such as an ALD process. For example, controller 130 is configured to operate substrate heater 108 to heat a substrate to a desired temperature. Controller 130 is also configured to operate flow control hardware 114 to flow a selected gas or mixture of gases at a selected rate into process chamber 102. Controller 130 is further configured to operate exhaust system 124 to remove gases from process chamber 102. Furthermore, controller 130 is configured to operate radiofrequency power source 128 to form a plasma comprising the oxygen-containing gas, as well as to control any other suitable functions of processing tool 100. Controller 130 may comprise any suitable computing system, examples of which are described below with reference to FIG. 13.

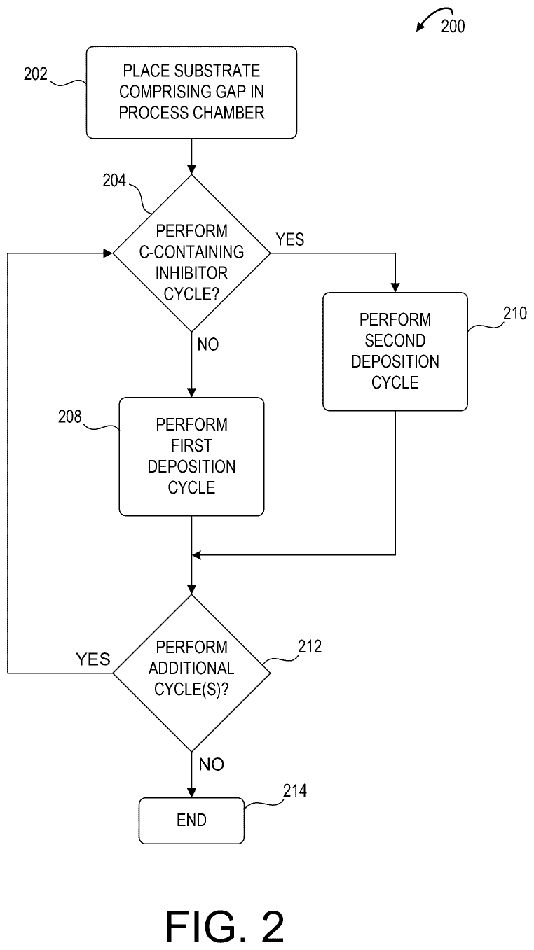

FIG. 2 shows a flow diagram of an example method 200 for performing a deposition process, such as a PEALD process using a carbon-containing inhibitor to produce a nonconformal oxide film. Method 200 may be performed, for example, using processing tool 100. Method 200 comprises, at 202, placing a substrate comprising one or more gaps into a process chamber. Any suitable substrate may be used. Examples include semiconductor wafers. The gaps on the substrate may comprise any suitable intermediate structure in an integrated circuit fabrication process. For example, the gaps may comprise channel gaps for a 3D NAND fabrication process. In some examples, method 200 may comprise heating the substrate via a substrate heater. In other examples, alternatively or additionally to including gaps, the substrate can include mandrels for use in forming oxide spacers, and/or any other suitable structures.

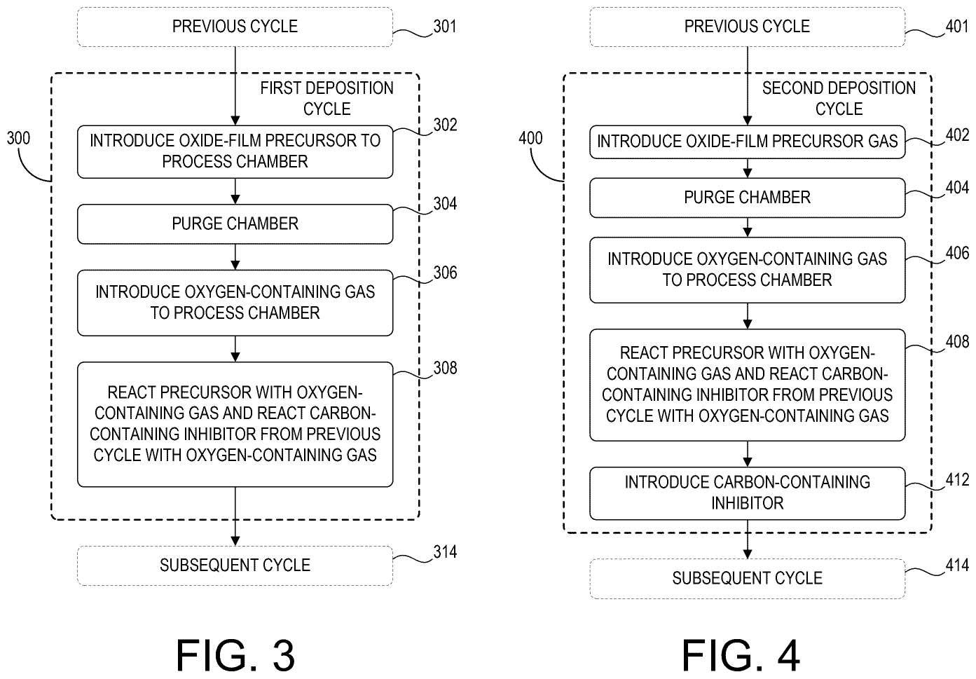

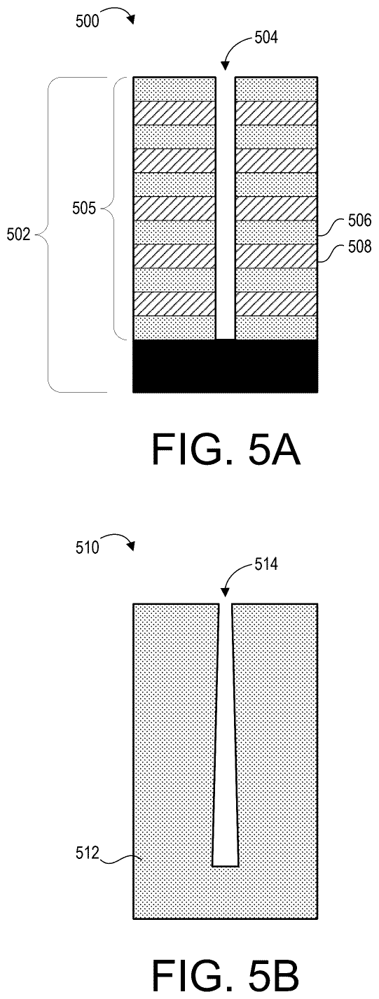

Nonconformal oxide film growth may comprise a plurality of deposition cycles, at least some of which include a carbon-containing inhibitor. Thus, method 200 further comprises, at 204, determining whether to perform a deposition cycle comprising a carbon-containing inhibitor, or a deposition cycle omitting the carbon-containing inhibitor. The determination may be based upon a recipe for a specific process being performed. The term “first deposition cycle” is used herein to represent a deposition cycle that omits introduction of a carbon-containing inhibitor. An example first deposition cycles is described in more detail with regard to FIG. 3. The term “second deposition cycle” is used herein to represent a deposition cycle that includes introduction of a carbon-containing inhibitor. An example second deposition cycle is described in more detail with regard to FIG. 4. As described in more detail below, a ratio of first deposition cycles to second deposition cycles can be varied to control a magnitude of film nonconformality. Further, a duration of carbon-containing inhibitor exposure in a deposition cycle also can be varied to control a magnitude of nonconformality. In some gap fill examples, the magnitude of nonconformality of a deposited film may be controlled based on a characteristic of a gap. Example characteristics of gaps include an aspect ratio of the gap, and whether a gap has reentrant features.

FIG. 3 shows a flow diagram depicting an example first deposition cycle 300 for forming an oxide film. The first deposition cycle 300 omits introducing a carbon-containing inhibitor. The first deposition cycle 300 may be preceded by a previous cycle, as indicated at 301. The previous cycle may be a prior first deposition cycle 300 or a prior second deposition cycle 400 as part of a nonconformal oxide film growth process.

First deposition cycle 300 comprises, at 302, introducing an oxide-film precursor into a process chamber. The oxide-film precursor may be selected to deposit conformally on the substrate. For example, the oxide-film precursor may form a monolayer of adsorbed oxide-film precursor on surfaces of the substrate, including surfaces within a gap. Where a silicon-containing oxide film is being deposited, example oxide-film precursors include polysilanes, siloxanes, aminosilanes, halosilanes, and organosilanes. As mentioned above, examples of silicon-containing precursors include materials having the general structure:

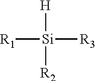

where R₁, R₂ and R₃ may be the same or different substituents, and may include silanes, siloxy groups, amines, halides, hydrogen, or organic groups, such as alkylamines, alkoxy, alkyl, alkenyl, alkynyl and aromatic groups.

Example silicon-containing precursors include polysilanes (H₃Si—(SiH₂)ₙ—SiH₃), where n≥1, such as silane, disilane, trisilane, tetrasilane, and trisilylamine.

In some examples, the silicon-containing precursor is an alkoxysilane. Alkoxysilanes that may be used include the following:
Hₓ—Si—(OR)_{y}, where x=1-3, x+y=4 and each R is a substituted or unsubstituted alkyl, alkenyl, alkynyl or aromatic group; and
Hₓ (RO)_{y}, —Si—Si—(OR)_{y}Hₓ, is a substituted or unsubstituted alkyl, alkenyl, alkynyl or aromatic group.

Examples of silicon-containing precursors include: include tetraethyl orthosilicate (TEOS), tetramethoxysilane (TMOS), methylsilane, trimethylsilane (3MS), ethylsilane, butasilanes, pentasilanes, octasilanes, heptasilane, hexasilane, cyclobutasilane, cycloheptasilane, cyclohexasilane, cyclooctasilane, cyclopentasilane, 1,4-dioxa-2,3,5,6-tetrasilacyclohexane, diethoxymethylsilane (DEMS), diethoxysilane (DES), dimethoxymethylsilane, dimethoxysilane (DMOS), methyl-diethoxysilane (MDES), methyl-dimethoxysilane (MDMS), t-butoxydisilane, triethoxysilane (TES), and trimethoxysilane (TMS or TriMOS).

In some examples, the silicon-containing precursor may be a siloxane. Example siloxanes include octamethylcyclotetrasiloxane (OMCTS), octamethoxydodecasiloxane (OMODDS), tetramethylcyclotetrasiloxane (TMCTS), triethoxysiloxane (TRIES), and tetraoxymethylcyclotetrasiloxane (TOMCTS).

As noted above, in some examples, the silicon-containing precursor may be an aminosilane, with hydrogen atoms, such as bisdiethylaminosilane, diisopropylaminosilane, tert-butylamino silane (BTBAS), or tris(dimethylamino) silane (3DMAS), di-sec-butylaminosilane. Aminosilane precursors include the following: Hₓ—Si—(NR) y, where x=1-3, x+y=4, and R is a substituted or unsubstituted alkyl, alkenyl, alkynyl or aromatic group or hydride group.

In some examples, a halogen-containing silane may be used such that the silane includes at least one hydrogen atom. Such a silane may have a chemical formula of SiXₐH_{y} where X is a halogen and y≥1. For example, dichlorosilane (H₂SiCl₂) may be used in some examples.

Where a metal oxide film is being deposited, example oxide-film precursors include HfCl₄, Hf(N(C₂H₅)₂)₄, Hf(OC(CH₃)₃)₄, TCl₄, Ti(OCH(CH₃)₂)₄, WF₆, WCl₆, W(CO)₆, SnCl₄, (CH₃)₄Sn, (C₂H₅)₄Sn, (CH₃)₂SnCl₂, Bu₂Sn(OMe)₂, Sn(NMe₂)₄, Me₂Sn(NMe₂)₂, Me₃Sn(NMe₂), MoCl₅, MoO₂Cl₂, MoOCl₄, and Mo(CO)₆.

Next, at 304, first deposition cycle 300 comprises purging the process chamber to remove at least some of the residual oxide-film precursor. As mentioned above, the chamber may be purged with an inert gas, such as argon. First deposition cycle 300 further comprises, at 306, introducing an oxygen-containing gas (e.g., oxygen, ozone, water vapor) into the process chamber.

At 308, first deposition cycle 300 comprises reacting the oxide-film precursor with the oxygen-containing gas. Further, any carbon-containing inhibitor deposited in a previous cycle 301 also may be reacted with the oxygen-containing gas at 308. Here, the carbon-containing inhibitor may compete with the oxide-film precursor for oxygen, thereby inhibiting growth of the oxide film. Inhibition may be more pronounced on surfaces with relatively greater absorption of the carbon-containing inhibitor.

The reaction can be performed using a radiofrequency power source to form a plasma comprising the oxygen-containing gas. For example, the radiofrequency power source may be operated at any suitable frequency (e.g., 400 kHz, 13.56 MHz) and power (e.g., between 0 and 7000 watts). The oxygen-containing gas can be converted to oxygen-containing reactive species via the plasma. The oxygen-containing reactive species can then react with the adsorbed monolayer of oxide-film precursor to form a layer of oxide film on the substrate. Example oxide films include silicon dioxide, silicon oxynitrides, silicon oxycarbides, hafnium oxide, titanium oxide, tungsten oxide, tin oxide, and molybdenum oxide. In other examples, the reaction may be performed using thermal energy, and/or any other suitable energy source. In some examples, an optional purge is performed following 308. When a radiofrequency power source is used to form a plasma, the optional purge may be performed after extinguishing the plasma. In some examples, the substrate is heated via a substrate heater during processing. In some examples, the substrate heater may be heated to a temperature within a range of 25° C. to 700° C. In more specific examples, the substrate heater may be heated to a temperature within a range of 25° C. to 75° C. In other examples, temperatures outside of these ranges may be used.

In other examples, a first deposition cycle 300 can be performed using TALD. In such examples, the reaction at 308 may be performed using thermal energy. Further, in other examples, first deposition cycle 300 may be performed via CVD by introducing the oxide-film precursor together with the oxygen-containing gas.

First deposition cycle 300 may be performed zero or more times during the processing of a substrate. First deposition cycle may precede a subsequent cycle 314, which may be a first deposition cycle 300 or second deposition cycle 400 as part of a nonconformal oxide film growth process. This is indicated by the “yes” branch at 212 in FIG. 2. First deposition cycle may be interspersed with second deposition cycles, such as example second deposition cycle 400, in any suitable order and at any suitable frequency.

As described above, a nonconformal oxide film deposition process comprises one or more deposition cycles in which a carbon-containing inhibitor is introduced. FIG. 4 shows a flow diagram depicting an example second deposition cycle 400. Second deposition cycle 400 includes introducing a carbon-containing inhibitor. An instance of second deposition cycle 400 can follow a previous cycle 401, which can be a first deposition cycle (e.g., example first deposition cycle 300) or a second deposition cycle (e.g., example second deposition cycle 400). Second deposition cycle 400 comprises, at 402, introducing an oxide-film precursor to the process chamber. As described above, the oxide-film precursor may be selected to adsorb conformally onto surface features of the substrate disposed within the process chamber. Where a silicon-containing oxide film is being deposited, example oxide-film precursors include polysilanes, siloxanes, aminosilanes, halosilanes, and organosilanes. Where a metal oxide film is being deposited, example oxide-film precursors include HfCl₄, Hf(N(C₂H₅)₂)+, Hf(OC(CH₃)₃)+, TCl₄, Ti(OCH(CH₃)₂)₄, WF₆, WCl₆, W(CO)₆, SnCl₄, (CH₃)₄Sn, (C₂H₅)₄Sn, (CH₃)₂SnCl₂, Bu₂Sn(OMe)₂, Sn(NMe₂)₄, Me₂Sn(NMe₂)₂, Me₃Sn(NMe₂), MoCl₅, MoO₂Cl₂, MoOCl₄, and Mo(CO)₆. At 404, second deposition cycle 400 comprises purging the process chamber to remove at least some of the residual oxide-film precursor gas. Second deposition cycle 400 further comprises, at 406, introducing an oxygen-containing gas to the process chamber. Example oxygen-containing gasses include oxygen, ozone, and water vapor. At 408, second deposition cycle 400 comprises reacting the oxygen-containing gas with the adsorbed oxide-film precursor. Deposition cycle 400 may comprise operating the radiofrequency power source at any suitable frequency (e.g., 400 kHz, 13.56 MHz) and any suitable power (e.g., between 0 and 6500 watts). In some examples, at 408, the method may also comprise reacting the oxygen-containing gas with a carbon-containing inhibitor that was deposited nonconformally in a previous cycle (e.g., a previous second deposition cycle 400). In some examples, the process chamber is optionally purged following the reaction at 408. Further, in some examples, the substrate heater is heated for second deposition cycle 400.

Second deposition cycle 400 further comprises, at 412, introducing a carbon-containing inhibitor to the process chamber. In some examples, the carbon-containing inhibitor may be introduced with the oxide-film precursor at 402. The carbon-containing inhibitor may be selected to deposit nonconformally on surface features of the substrate disposed within the process chamber. The carbon-containing inhibitor is selected to form a gas-phase oxidized carbon species (e.g., CO and/or CO₂, as well as other oxides, such as nitrogen oxides, depending upon constituent atoms of the carbon-containing inhibitor) when adsorbed to the substrate surface and exposed to reactive oxygen-containing species. Any suitable carbon-containing inhibitor may be used. In some examples, the carbon-containing inhibitor may comprise an alkane comprising a general formula CₙH₂ₙ₊₂ in which n=1 to 10. Examples of suitable alkanes may include methane, ethane, propane, butane, pentane, hexane, and substituted linear alkanes. Other examples of carbon-containing inhibitors may comprise an alkene, an alkyne, a cyclic hydrocarbon, an aromatic, an alcohol, a diol, an aldehyde, an ester, an ether, a ketone, an alkyl halide, an alkyl amine, or an alkyl diamine. In still other examples, the carbon-containing inhibitor may comprise a mixture of carbon-containing inhibitors. Examples of suitable alkenes (CₙH₂ₙ in which n=2 to 10, for an alkene with a single carbon-carbon double bond) may include ethene, propene, and butene. Examples of suitable alkynes (CₙH₂ₙ₋₂ in which n=2 to 10, for an alkyne with a single carbon-carbon triple bond) may include acetylene, propyne, and butyne. Examples of suitable cyclic hydrocarbons may include cyclobutene, cyclopentane and cyclohexane. Examples of suitable aromatics may include benzene, toluene, pyridine, and pyrimidine. Examples of suitable alcohols may include methanol, ethanol, and propanol. Examples of suitable diols may include ethylene glycol, propylene glycol, and hydroquinone. Examples of suitable aldehydes may include formaldehyde and acetaldehyde. Examples of suitable esters may include ethyl formate, methyl acetate, and ethyl acetate. Examples of suitable ethers may include diethyl ether, methyl phenyl ether, and aromatic ethers such as furan. Examples of suitable ketones may include acetone and methyl ethyl ketone. Examples of suitable alkyl halides may include ethyl fluoride, isopropyl bromide, and t-butyl chloride. Examples of suitable alkyl amines may include methylamine, dimethylamine, trimethylamine, and piperidine. Examples of suitable alkyl diamines may include ethylenediamine and 1,3-diaminopropane.

Second deposition cycle 400 may be performed any suitable number of times during the processing of a substrate. Second deposition cycle 400 may follow a previous deposition cycle 401 and may precede a subsequent deposition cycle 414, each of which may comprise a first deposition cycle 300 or a second deposition cycle 400. In a subsequent deposition cycle 414, the oxygen-containing gas can react with the adsorbed carbon-containing inhibitor, which consumes the oxygen-containing gas, thereby inhibiting the precursor reaction. As the carbon-containing inhibitor adsorbs nonconformally to the substrate, the inhibition of the oxide film formation may be stronger where more of the carbon-containing inhibitor is deposited.

In some examples, the substrate is heated via a substrate heater during the second deposition cycle. In some examples, the substrate heater may be heated to a temperature within a range of 25° C. to 700° C., or to a higher temperature in some examples. Further, in some examples, the substrate heater may be heated to a temperature within a range of 25° C. to 75° C. In other examples, temperatures outside of these ranges may be used. The temperature may be determined based at least on properties of the carbon-containing inhibitor, such as the boiling point, vapor pressure, and/or sticking coefficient of the carbon-containing inhibitor at a selected temperature and pressure.

In other examples, a second deposition cycle 400 can be performed using TALD. In such examples, the reaction at 408 may be performed using thermal energy. Further, in other examples, second deposition cycle 400 may be performed via CVD by introducing the oxide-film precursor together with the oxygen-containing gas.

Returning to FIG. 2, when it is determined at 204 to run an oxide film deposition cycle without the carbon-containing inhibitor, method 200 comprises performing first deposition cycle at 208. As mentioned above, deposition cycle 300 of FIG. 3 is an example of first deposition cycle 208. Likewise, when it is determined at 204 to run an oxide film deposition cycle with the carbon-containing inhibitor, method 200 comprises performing second deposition cycle 210. As mentioned above, deposition cycle 400 of FIG. 4 is an example of second deposition cycle 210. The relative proportion of deposition cycles with a carbon-containing inhibitor may be varied based upon a desired amount of nonconformality of the oxide film. As described below, additional second deposition cycles may result in greater differences in thickness on different surfaces within a gap and/or on different aspects of different substrate features. As such, method 200 may comprise a greater number of second deposition cycles when a greater amount of nonconformality is desired. Additionally or alternatively, method 200 may comprise one or more second deposition cycles that expose the substrate to the carbon-containing inhibitor for a relatively longer duration when a greater amount of nonconformality is desired.

As discussed below, various factors, including a ratio of first deposition cycles 208 to second deposition cycles 210, can be adjusted to control the degree of nonconformal growth. At 212, method 200 may perform additional deposition cycles, e.g., according to an overall process for a desired film. If additional deposition cycles are to be performed, the method returns to 204. Additional cycles result in thicker oxide film growth. A greater proportion of cycles including introduction of the carbon-containing inhibitor results in greater nonconformality. Any suitable number of deposition cycles may be performed. When the oxide film reaches a suitable thickness, the method may proceed from 212 to 214 and terminate.

In some examples, a low temperature SiO₂ blanket oxide deposited according to the present disclosure may comprise a thickness within a range of 75 Å to 175 Å. In some examples, the thickness may vary by ≤0.2% (R/2). Further, in some examples, the substrate-to-substrate thickness may vary by ≤0.70% (range of mean of 25 substrates, continuous run). In some examples, a SiO₂ blanket oxide may comprise a wet etch rate and/or dry etch rate that is tunable. In some examples, a SiO₂ blanket oxide may comprise ≤10 adder defects at 30 nm. In some examples a SiO₂ blanket oxide may comprise a bulk modulus within a range of 70 GPa to 80 GPa. In some examples, a SiO₂ blanket oxide may comprise a density within a range of 2.1 to 2.2 g/cm³. In some examples, a SiO₂ blanket oxide may be formed with a core loss ≤10 Å. In some examples, a SiO₂ blanket oxide may comprise a carbon concentration of ≤ 0.5% and/or a nitrogen concentration of ≤0.5%. In other examples, an oxide film may have one or more values outside of these ranges.

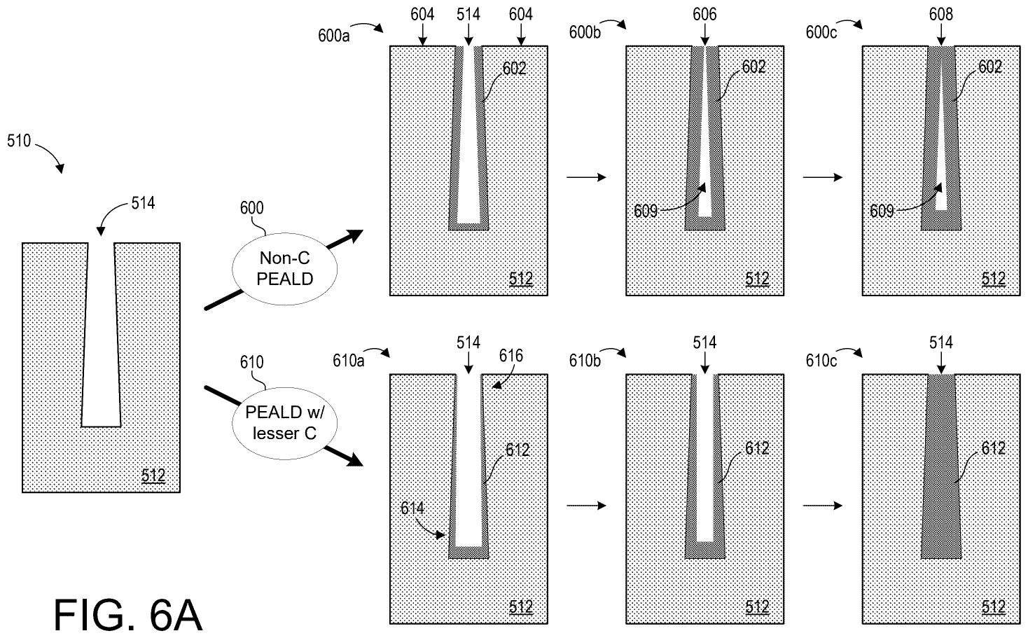

The oxide film deposition processes described herein may be used to fill any suitable gap in any suitable substrate. FIGS. 5A-5B show example substrates comprising gaps. FIG. 5A schematically shows an example of an intermediate structure 500 comprising a substrate 502 having a gap 504. More specifically, intermediate structure 500 comprises a stack 505 of alternating layers 506, 508. Layers 506, 508 may comprise alternating oxide/nitride layers or alternating oxide/polysilicon layers in some examples. Intermediate structure 500 may represent an intermediate structure in a 3D NAND flash memory fabrication process. In such examples, gap 504 may represent a channel gap for forming a channel in a 3D NAND flash memory device. In other examples, intermediate structure 500 may represent a structure formed during a 3D dynamic random-access memory (DRAM) fabrication process.

Gap 504 comprises a relatively high aspect ratio. For example, gap 504 may comprise an aspect ratio within a range of 40:1 to 100:1. It will be understood that gaps and other substrate features depicted herein may not be drawn to scale.

FIG. 5B schematically shows an example intermediate structure 510 comprising a substrate 512 including a reentrant gap 514. Substrate 512 is a generalization of substrate 502. In this example, reentrant gap 514 comprises a reentrant profile that includes negatively sloped sidewalls. The term “negatively sloped sidewalls” indicates a sidewall that extends underneath an edge of an opening of a gap. The opening of gap 514 at the substrate surface is narrower than the width of the bottom of the gap. In other examples, a gap may comprise other types of reentrant features than sloped sidewalls. Intermediate structure 510 is representative of any suitable reentrant intermediate structure in an integrated circuit fabrication process.

As discussed above, it may be challenging to fill a reentrant gap or high aspect ratio gap with an oxide film using PEALD while avoiding forming voids. For example, with regard to high aspect ratio structures, the oxide-film precursor and/or oxygen-containing gas may have a higher deposition rate within the gap at locations closer to the gap opening than locations deeper within the gap. Further, even where growth rates are uniform throughout a gap depth, conformal film growth can pinch off a reentrant gap before completely filling a deeper portion of a gap, as the narrower portion of the gap can close off before wider portions that are deeper within the gap.

Thus, nonconformal film growth according to the present disclosure can be used to address such challenges. As mentioned above, various process variables may be adjusted to affect a degree of film conformality. As one example, varying a time of exposure to the carbon-containing inhibitor in an oxide deposition cycle may vary a conformality of the oxide film. In such an example, a longer exposure time may lead to greater nonconformality. As another example, a ratio of first oxide deposition cycles to second oxide deposition cycles may be varied to vary a conformality of the resulting oxide film.

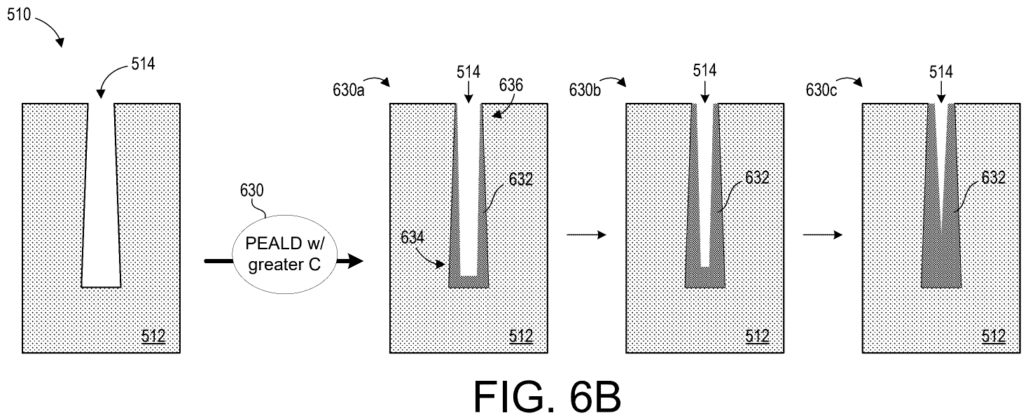

FIGS. 6A and 6B schematically show example gap fill processes performed on intermediate structure 510 under different process conditions. Process 600 may represent an ALD oxide film deposition process performed without the use of a carbon-containing inhibitor. Film deposition on substrate regions 604 adjacent to gap 514 is not shown in FIGS. 6A-6B for clarity. At 600a conformal growth of a partial thickness of an oxide film 602 results in a conformal narrowing of the gap 514. At 600b, continued conformal growth of oxide film 602 has further narrowed the opening of the gap, as indicated at 606. At 600c, the opening of the gap has been completely pinched off, as indicated at 608. As a result, a void 609 enclosed by oxide thin film 602 is formed.

To avoid the formation of such voids, process 610 utilizes one or more oxide film deposition cycles comprising introduction of a carbon-containing inhibitor to thereby grow a film nonconformally, as described above. Process 610 comprises introducing a first, lesser amount of carbon-containing gas to the process chamber. As shown at 610a, oxide film 612 has grown relatively thicker at the bottom of the gap at 614 compared to sidewalls near the opening at 616. At 610b, continued film growth narrows gap 514 relatively uniformly through the depth of the gap. Finally, at 610c, gap 514 is nearly completely filled, with no void formation.

The duration and frequency of exposure of carbon-containing gas can be controlled via adjusting various parameters in the PEALD process. For example, an oxide film deposition process may comprise performing n first deposition cycles 300 followed by m second deposition cycles 400. The numbers n and m may be any suitable integers. These steps may be repeated any suitable number of times. In such examples, the proportion P of oxide film deposition cycles which include introducing the carbon-containing inhibitor may be determined by

$$P = \frac{m}{n + m} .$$

In some examples, n and m may vary during the processing of a substrate. Additionally, in some examples, the proportion P may be between 5% and 50%. In some such examples, the proportion P may be between 10% and 20%.

FIG. 6B shows intermediate structures formed by an example process 630 that utilizes a greater proportion P of second deposition cycles, and/or longer exposures to a carbon-containing inhibitor, compared to process 610 in FIG. 6A. Whereas the gap 514 narrowed substantially uniformly in process 610, process 630 results in filling a bottom portion of gap 514 well before filling a top portion of gap 514. For example, at 630a, oxide film 632 is relatively thicker on gap sidewalls in a bottom portion of the gap at 634, and is relatively thinner on sidewalls in an upper portion of the gap at 636. Intermediate structures shown at 630b and 630c show oxide film 632 at further stages of growth, and illustrate that the gap fills from bottom to opening with no void formation.

Compared to oxide film 612, oxide film 632 shows a relatively greater magnitude of nonconformal growth. As such, exposing the gap to the carbon-containing inhibitor for a relatively longer duration and/or a greater number of cycles comprising a carbon-containing inhibitor may provide a greater magnitude of nonconformal growth.

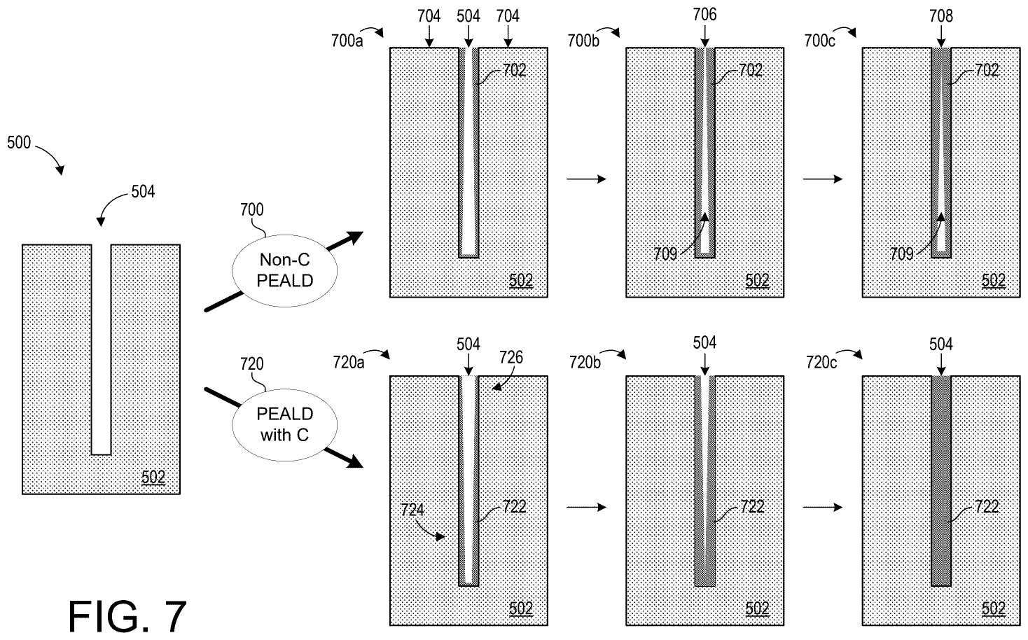

FIG. 7 schematically shows example gap fill processes performed on intermediate structure 500 under different process conditions. In this figure, the layers of intermediate structure 500 are omitted for clarity. Further, intermediate structure 500 is representative of any relatively high-aspect ratio intermediate structure in a substrate other than the layered structure and channel gap of FIG. 5.

Process 700 may represent an ALD oxide film deposition process performed without the use of a carbon-containing inhibitor. Film deposition on substrate regions 704 adjacent to gap 504 is not shown in FIG. 7 for clarity. At 700a, growth of a partial thickness of an oxide film 702 results in a narrowing of the gap 504. Oxide film 702 may grow slower at the bottom of the gap and grow faster closer to the opening of the gap outside a saturation regime. At 700b, continued growth of oxide film 702 has further narrowed the opening of the gap, as indicated at 706. At 700c, the opening of the gap has been completely pinched off, as indicated at 708 forming a void 709 enclosed by oxide thin film 702.

FIG. 7 further shows intermediate structures formed by an example process 720 that utilizes a carbon-containing inhibitor during ALD cycles. As shown at 720a, oxide film 722 has grown relatively thicker at the bottom of gap 504 at 724 compared to sidewalls near the opening at 726. At 720b, continued film growth narrows gap 504 while the bottom of the gap continues to fill. Finally, at 720c, gap 504 is completely filled, with no void formation.

As mentioned above, a ratio of a number of oxide film deposition cycles comprising a carbon-containing inhibitor to a number of cycles omitting the carbon-containing inhibitor may be selected to achieve a desired degree of nonconformal growth film growth such as those shown at 610 or 630 of FIGS. 6A-6B, thereby avoiding the formation of voids. Additionally or alternatively, a duration of carbon-containing gas exposure in one or more cycles comprising a carbon-containing inhibitor may be selected to achieve a desired magnitude of nonconformal oxide film growth.

In some examples, oxide film structures may be formed with a seam depth ≥1 μm. In some examples, the seam nonuniformity within a substrate is between +/−5 nm. In some examples, oxide film structures may bow with a delta ≤80 μm. In some examples, a bottom deck fill percentage of an oxide film structure is ≥70%. In some examples, a blanket oxide may be formed with a wet etch rate ratio ≤6. In some examples, a blanket oxide may have a nonuniformity within a substrate ≤2%. In some examples, a blanket oxide may have a substrate-to-substrate nonuniformity ≤0.5%. In some examples, a blanket oxide may have ≤10 defects at 60 nm. In other examples, oxide film structures may have one or more values outside of these example ranges.

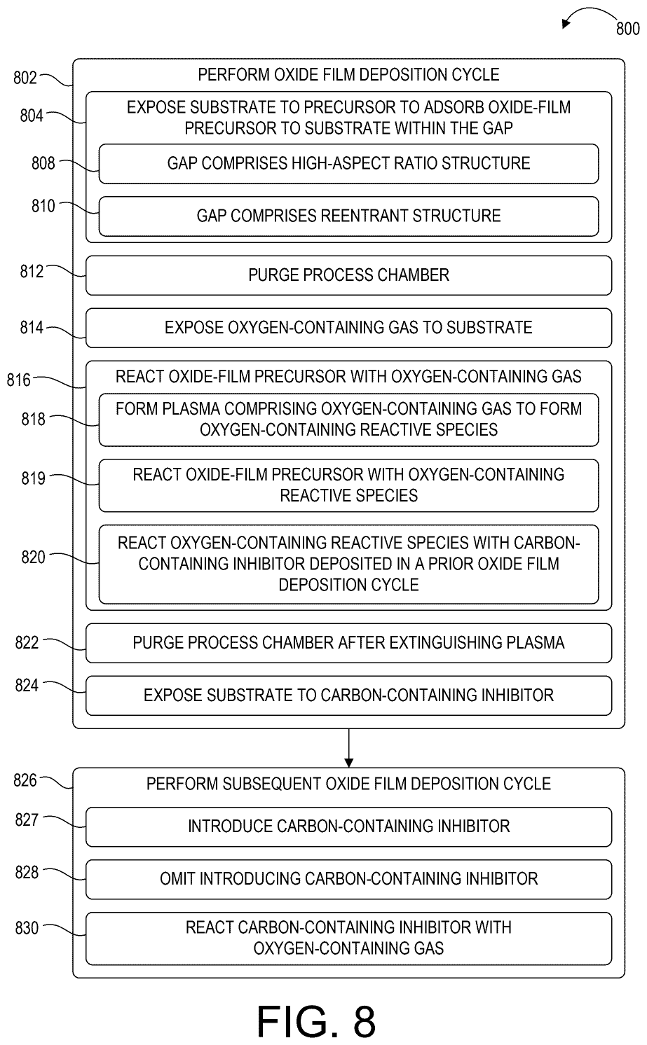

FIG. 8 shows a flow diagram illustrating an example method 800 for performing atomic layer deposition to fill a gap on a substrate disposed within a process chamber. At 802, method 800 comprises performing at least one oxide film deposition cycle. In some examples, a plurality of oxide film deposition cycles are performed. First deposition cycle 300 and second deposition cycle 400 are examples of oxide film deposition cycles.

At 804, oxide film deposition cycle 802 comprises exposing the substrate to an oxide-film precursor to adsorb oxide-film precursor to the substrate within the gap. In some examples, the gap is formed in alternating layers of material. For example, the substrate may comprise a stack of alternating layers of different materials (e.g., 3D NAND or 3D DRAM). In other examples, the substrate may comprise any other suitable structure. Any suitable oxide-film precursor may be used. In the case of a silicon-containing oxide film, example oxide-film precursors include polysilanes, siloxanes, aminosilanes, halosilanes, and organosilanes, such as those described in more detail above. Example oxide-film precursors for metal oxide films include HfCl₄, Hf(N(C₂H₅)₂)₄, Hf(OC(CH₃)₃)₄, TCl₄, Ti(OCH(CH₃)₂)₄, WF₆, WCl₆, W(CO)₆, SnCl₄, (CH₃)₄Sn, (C₂H₅)₄Sn, (CH₃)₂SnCl₂, Bu₂Sn(OMe)₂, Sn(NMe₂)₄, Me₂Sn(NMe₂)₂, Me₃Sn(NMe₂), MoCl₅, MoO₂Cl₂. MoOCl₄, and Mo(CO)₆.

In some examples, as indicated at 808, the gap comprises a relatively high aspect ratio, such as within a range of 40:1 to 100:1. In other examples, the gap may comprise an aspect ratio outside of this range. Further, in some examples, as indicated at 810, the gap comprises a reentrant structure.

Continuing, at 812, performing the oxide film deposition cycle 802 may optionally comprise purging the process chamber after introducing the oxide-film precursor to the process chamber. Purging the process chamber may be performed to remove at least some residual oxide-film precursor.

At 814, performing the oxide film deposition cycle 802 comprises exposing an oxygen-containing gas to the substrate. Any suitable oxygen-containing gas may be used. Examples include oxygen, ozone, and water vapor. Oxide film deposition cycle 802 further comprises, at 816, reacting the oxide-film precursor with the oxygen-containing gas. Where the oxide film deposition cycle is performed using PEALD, at 818, method 800 comprises forming a plasma comprising the oxygen-containing gas to form oxygen-containing reactive species. In such examples, method 800 further includes, at 819, oxidizing the oxide-film precursor by reacting the oxide-film precursor with the oxygen-containing reactive species, thereby forming an oxide film. In some examples, at 820, at least some oxygen-containing reactive species in the plasma react with adsorbed carbon-containing inhibitor that was deposited nonconformally in a prior oxide film deposition cycle, which may reduce the availability of the oxygen-containing reactive species for reacting with oxide-film precursor and thereby inhibit oxide film growth. In some examples, at 822, the method comprises purging the process chamber after extinguishing plasma.

In at least some deposition cycles, method 800 comprises, at 824, exposing the substrate to a carbon-containing inhibitor. As described above, any suitable carbon-containing inhibitor may be used. In some examples, the carbon-containing inhibitor comprises an alkane comprising a general formula CₙH₂ₙ₊₂ in which n=1 to 10. In some examples, the alkane comprises one or more of methane, ethane, propane, butane, pentane, or hexane. Further, in some examples, the carbon-containing inhibitor comprises one or more of an alkene, an alkyne, a cyclic hydrocarbon, an aromatic, an alcohol, a diol, an aldehyde, an ester, an ether, an alkyl halide, an alkyl amine, or an alkyl diamine. In some examples, the alkane comprises a substituted linear alkane. In still other examples, the carbon-containing inhibitor may comprise a mixture of carbon-containing inhibitors. Examples of suitable alkenes (CₙH₂ₙ for alkenes with a single carbon-carbon double bond, in which n=2 to 10) may include ethene, propene, and butene. Examples of suitable alkynes (CₙH₂ₙ₋₂ for alkynes comprising a single carbon-carbon triple bond, in which n=2 to 10) may include acetylene, propyne, and butyne. Examples of suitable cyclic hydrocarbons may include cyclobutene, cyclopentane and cyclohexane. Examples of suitable aromatics may include benzene, toluene, pyridine, and pyrimidine. Examples of suitable alcohols may include methanol, ethanol, and propanol. Examples of suitable diols may include ethylene glycol, propylene glycol, and hydroquinone. Examples of suitable aldehydes may include formaldehyde and acetaldehyde. Examples of suitable esters may include ethyl formate, methyl acetate, and ethyl acetate. Examples of suitable ethers may include diethyl ether, methyl phenyl ether, or aromatic ethers such as furan. Examples of suitable ketones may include acetone and methyl ethyl ketone. Examples of suitable alkyl halides may include ethyl fluoride, isopropyl bromide, and t-butyl chloride. Examples of suitable alkyl amines may include methylamine, dimethylamine, trimethylamine, and piperidine. Examples of suitable alkyl diamines may include ethylenediamine and 1,3-diaminopropane.

Method 800 may further comprise, at 826, performing one or more subsequent oxide film deposition cycles. In some examples, at 827, a subsequent oxide film deposition cycle may comprise introducing a carbon-containing inhibitor (e.g., second deposition cycle 400). Further, in some examples, at 828, a subsequent oxide film deposition cycle omits introducing the carbon-containing gas (e.g., first deposition cycle 300). Additionally, at 830, in some examples, the subsequent oxide film deposition cycle comprises reacting the carbon-containing inhibitor introduced at 824 with the oxygen-containing gas.

Thus, the examples disclosed herein may provide for filling one or more gaps on a substrate in manners that can avoid formation of voids. While disclosed in the contexts of gaps with relatively high aspect ratios or reentrant features, the disclosed examples can be used to fill any suitable gap.

In some examples, structures may be formed on a substrate with an as-deposited critical dimension space imbalance uniformity (3 sigma)≤5 Å. In some examples, spacers may be formed comprising a squareness ≥90%. In some examples, a maximum space imbalance may be ≤5 Å. In some examples, the as deposited critical dimension stability may be ≤2 Å as measured as a mean of a 6-substrate run. In some examples, a structure may comprise a line width roughness ≤15 Å. In some examples, a structure may comprise a line edge roughness of ≤11 Å. In some examples, a structure may comprise a sidewall roughness of ≤15 Å. In other examples, structures may have one or more values outside of these example ranges.

The examples described herein may provide for the efficient formation of films and/or structures on a substrate with a relatively high degree of control over feature sizes, film thickness, uniformity, and other characteristics. In some examples, throughput for forming a low temperature oxide-type film may be ≥125 substrates per hour per chamber. In some examples, throughput for forming a low temperature hard mask-type film may be ≥90 substrates per hour per chamber. In some examples, a SiO₂ blanket oxide may be formed with chemistry usage that is ≤2.6 mg per cycle. In some examples, a SiO₂ blanket oxide may comprise an accumulation limit ≥3.0 μm. In other examples, a film may have one or more values outside of these example ranges.

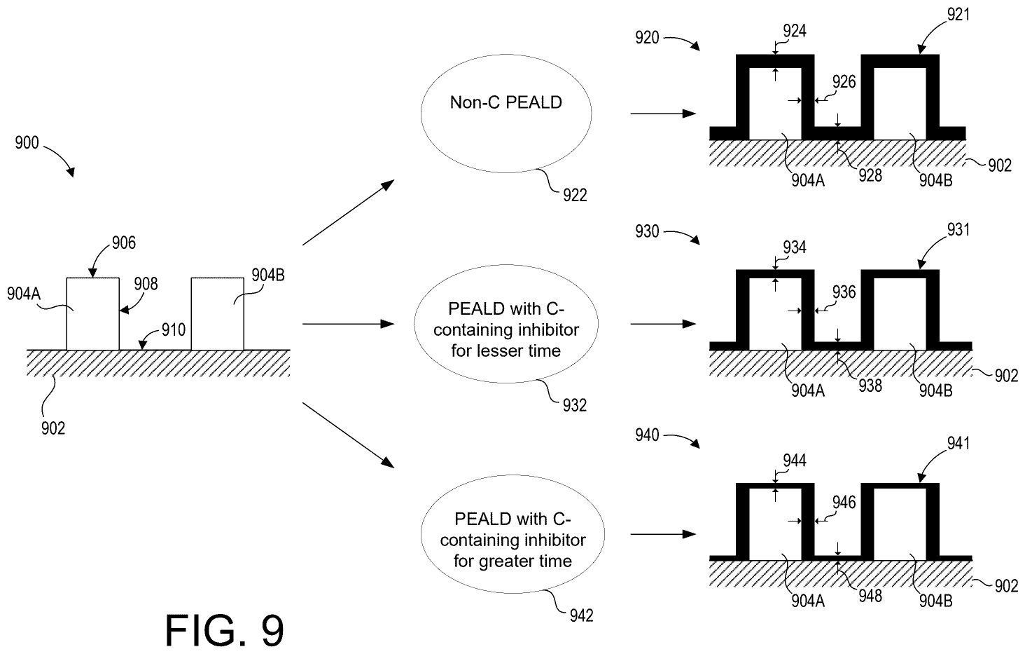

As another example, FIG. 9 schematically shows oxide film growth on an intermediate structure 900 under different processing conditions. Intermediate structure 900 may represent any suitable intermediate structure in an integrated circuit manufacturing process. Intermediate structure 900, shown here in a schematic cross-sectional view, comprises substrate 902. Intermediate structure 900 further comprises surface features, which in this example are mandrels 904A-B for a patterning process (e.g., SADP). Substrate 902 represents any suitable structure on which mandrels 904A-B may be formed. Mandrels 904A-B may comprise any suitable dimensions. In some examples, mandrels 904A-B may have a cross-sectional width of 10-100 nm. Mandrels may comprise any suitable material. Examples include polysilicon, amorphous silicon, silicon oxides, silicon nitrides, or carbon. Mandrels 904A-B may be formed on substrate 902 via any suitable process. For example, mandrels 904A-B may be formed via application of spin-on carbon, followed by lithographic patterning. Each mandrel comprises a top horizontal surface 906 and sidewall surfaces 908, with a lower horizontal substrate surface 910 between mandrel 904A and 904B.

FIG. 9 also shows three processed intermediate structures after growth of an oxide film. Processed intermediate structure 920 represents conformal oxide film growth using a non-carbon PEALD process 922 that omits using a carbon-containing inhibitor. As shown, the thickness 924 of oxide film 921 at an upper horizontal surface of mandrel 904A is substantially equal to the thickness 926 along the vertical surface of the mandrel 904A, as well as the thickness 928 of the oxide film deposited on a lower substrate surface between two mandrels 904A and 904B. The uniform thickness of the conformal oxide film 921 indicates a non-controllable growth of oxide film over different surfaces in the absence of carbon-containing inhibitor.

Processed intermediate structure 930 represents a nonconformal oxide film 931 formed using a PEALD process 932 utilizing a carbon-containing inhibitor. Carbon-inhibited PEALD process 932 comprises introducing a carbon-containing inhibitor to the process chamber for a first, shorter duration during each second deposition cycle 400. As shown at thickness 934, oxide film 931 is substantially thinner on an upper horizontal surface of mandrel 904A than at thickness 936 on a vertical surface of mandrel 904A. Thickness 934 on the upper horizontal surface of mandrel 904 is substantially equal to the thickness 938 on the lower horizontal substrate surface. Such nonconformal growth results from the carbon-containing inhibitor nonconformally adsorbing onto surfaces of different orientations, thus providing relatively greater inhibition on horizontal surfaces 906, 910 and relatively lesser inhibition on vertical surfaces 908.

Processed intermediate structure 940 schematically shows the result of growing an oxide film 941 while introducing a carbon-containing inhibitor to the process chamber for a second, longer duration during each second deposition cycle 400. Increased exposure time to the carbon-containing inhibitor results in a relatively greater magnitude of nonconformality for PEALD process 942 compared to PEALD process 932. As depicted in FIG. 9, the thickness 944 of film 941 at an upper horizontal surface is less than the thickness 934 of film 931 on a similar horizontal surface. Thickness 948 on a lower horizontal substrate surface is similar to thickness 944. In some examples, the top: sidewall ratio (thickness 944: thickness 946) ranges from 0.99 to 0.50, with smaller ratios associated with longer exposure durations of the carbon-containing inhibitor. In other examples, the top: sidewall ratio may have any other suitable value.

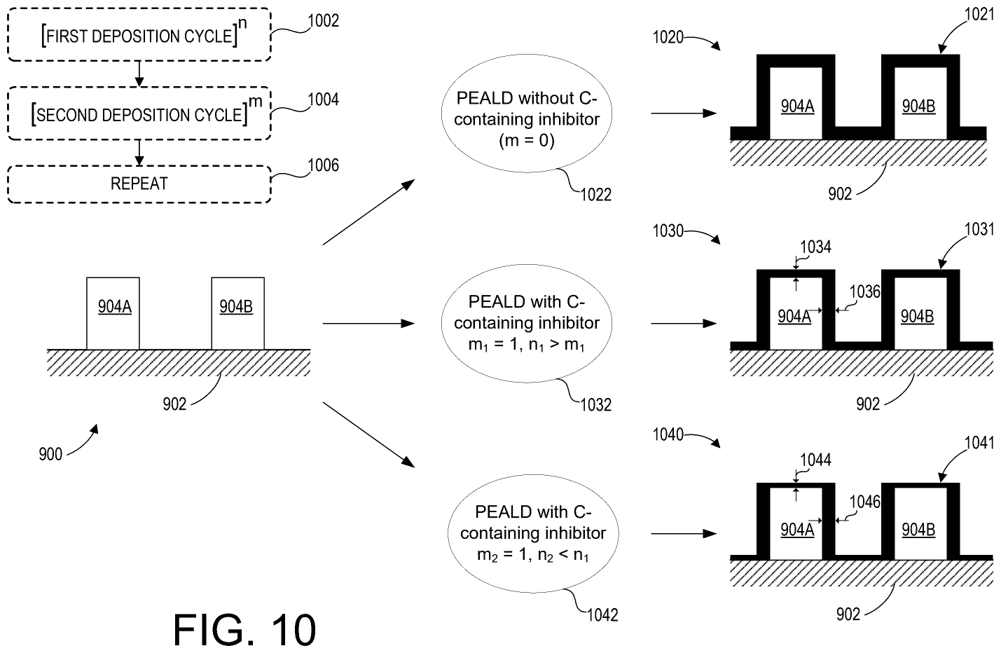

FIG. 10 schematically shows examples of nonconformal oxide film growth on intermediate structure 900 where the proportion of carbon-inhibited deposition cycles is varied. In this example, an oxide film deposition process may comprise performing n first deposition cycles 300 (shown at 1002) followed by m second deposition cycles 400 (shown at 1004). The numbers n and m may be any suitable integers. These steps may be repeated at 1006 any suitable number of times. As such, the proportion P of oxide film deposition cycles which include introducing the carbon-containing inhibitor may be determined by

$$P = \frac{m}{n + m} .$$

In some examples, n and m may vary during the processing of a substrate. Additionally, in some examples, the proportion P may be between 5% and 50%. In some such examples, the proportion P may be between 10% and 20%.

Processed intermediate structure 1020 comprises an oxide film 1021 grown using non-carbon PEALD process 1022. Non-carbon PEALD process 1022 comprises a plurality of first deposition cycles 300, where m=0. As such, oxide film 1021 is deposited conformally.

Processed intermediate structure 1030 schematically shows the result of growing an oxide film 1031 using carbon-inhibited PEALD process 1032. Carbon-inhibited PEALD process 1032 comprises performing m first deposition cycles 300, performing one second deposition cycle 400, and repeating, where m>1. As shown, oxide film 1031 is thinner at an upper horizontal surface (thickness 1034) than at a vertical surface (thickness 1036).

Processed intermediate structure 1040 schematically shows the result of growing an oxide film 1041 using a carbon-inhibited PEALD process 1042, where the proportion of second deposition cycles 400 performed is relatively greater than PEALD process 1032. Carbon-inhibited PEALD process 1042 comprises performing m₂ first deposition cycles 300, performing one second deposition cycles 400 of time t, and repeating, where m₂>1 and m₂<m₁. As such, the proportion P₂ is greater than P₁, where

$${P}_{2} = \frac{1}{{n}_{2} + 1} and {P}_{1} = \frac{1}{{n}_{1} + 1} .$$

Thickness 1044 of oxide film 1041 at an upper horizontal surface is relatively lesser compared to thickness 1046 at a vertical surface. Further, as a result of performing a greater proportion of second deposition cycles, PEALD process 1042 produces oxide film 1041 that is relatively thinner on top of mandrels (i.e., at thickness 1044) compared to oxide film 1031 (i.e., at thickness 1034). As such, a relatively greater proportion of carbon-inhibited deposition cycles may result in an oxide film with a greater degree of nonconformal growth.

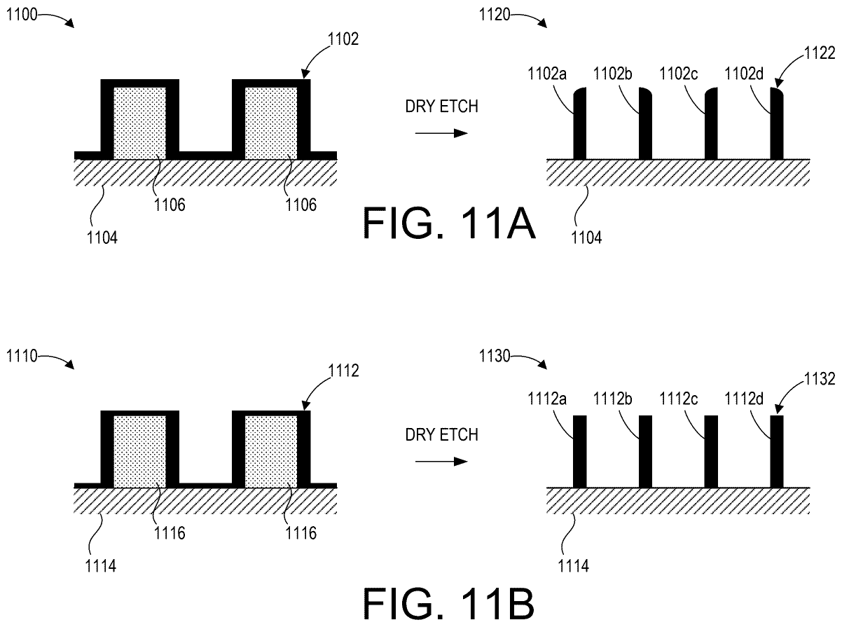

As described above, controllable nonconformal growth of oxide films may have various uses in device fabrication. Examples include patterning processes, such as SADP processes. FIG. 11A schematically shows a cross-sectional view of an intermediate structure 1100 comprising an oxide film 1102 that has been grown nonconformally over a substrate 1104 and mandrels 1106 via a PEALD process that utilizes a first, lesser amount of carbon-containing inhibitor gas (e.g., via PEALD process 932 or PEALD process 1032). In contrast, intermediate structure 1110 of FIG. 11B comprises an oxide film 1112 that has been grown nonconformally over a substrate 1114 and mandrels 1116 using a second, greater amount of carbon-containing inhibitor gas (e.g., PEALD process 942 or PEALD process 1042).

The oxide film on top of, and between, the mandrels is removed via dry etching. As illustrated in FIG. 11A, the result of performing a dry etch on intermediate structure 1100 is shown at 1120. Mandrels 1106 have been removed, leaving spacers 1102a-d. As seen at 1122, spacer 1102d is tapered at the top. Such tapering of spacers may negatively affect transfer etch performance. Such tapering may be more pronounced for longer etch times. Further, longer etch times and tapering may be associated with use of a relatively lesser amount of carbon-containing inhibitor gas.

As illustrated in FIG. 11B, the result of performing a dry etch on intermediate structure 1110 is shown at 1130. The top layer of oxide film 1112 is etched away in order to remove mandrels 1116. As a result of the dry etch, square spacers 1112a-d remain. As the top of nonconformal oxide film 1112 is relatively thinner compared to oxide film 1102, the dry etch process may be performed for less time compared to the example at 1120. With a reduction in dry etch time, the sidewalls of oxide film 1112 are exposed to dry etch chemistry for less time. Due to the reduction in dry etch time, the square spacers 1112a-d comprise square-shaped tops (e.g., see 1132 of square spacer 1112d). As such, using a carbon-containing inhibitor gas during PEALD to form a nonconformal oxide film may help to avoid tapering compared to the use of a conformal oxide film. Such square spacers may provide for relatively better transfer etch performance. In some examples, structures such as these may be formed on a substrate with an as-deposited critical dimension space imbalance uniformity (3 sigma)≤5 Å. In some examples, spacers may be formed comprising a squareness ≥90%. In some examples, a maximum space imbalance may be ≤5 Å. In some examples, an as deposited critical dimension stability may be ≤2 Å as measured as a mean of a 6-substrate run. In some examples, a structure may comprise a line width roughness ≤15 Å. In some examples, a structure may comprise a line edge roughness of ≤11 Å. In some examples, a structure may comprise a sidewall roughness of ≤15 Å. In some examples, oxide film structures may be formed with a seam depth ≥1 μm. In some examples, the seam nonuniformity within a substrate is between +/−5 nm. In some examples, oxide film structures may bow with a delta ≤80 μm. In some examples, a bottom deck fill percentage of an oxide film structure is ≥70%. In some examples, a blanket oxide may be formed with a wet etch rate ratio ≤6. In some examples, a blanket oxide may have a nonuniformity within a wafer ≤2%. In some examples, a blanket oxide may have a wafer-to-wafer nonuniformity ≤0.5%. In some examples, a blanket oxide may have ≤10 defects at 60 nm. In other examples, oxide film structures may have one or more values outside of these example ranges. In other examples, structures may have one or more values outside of these example ranges.

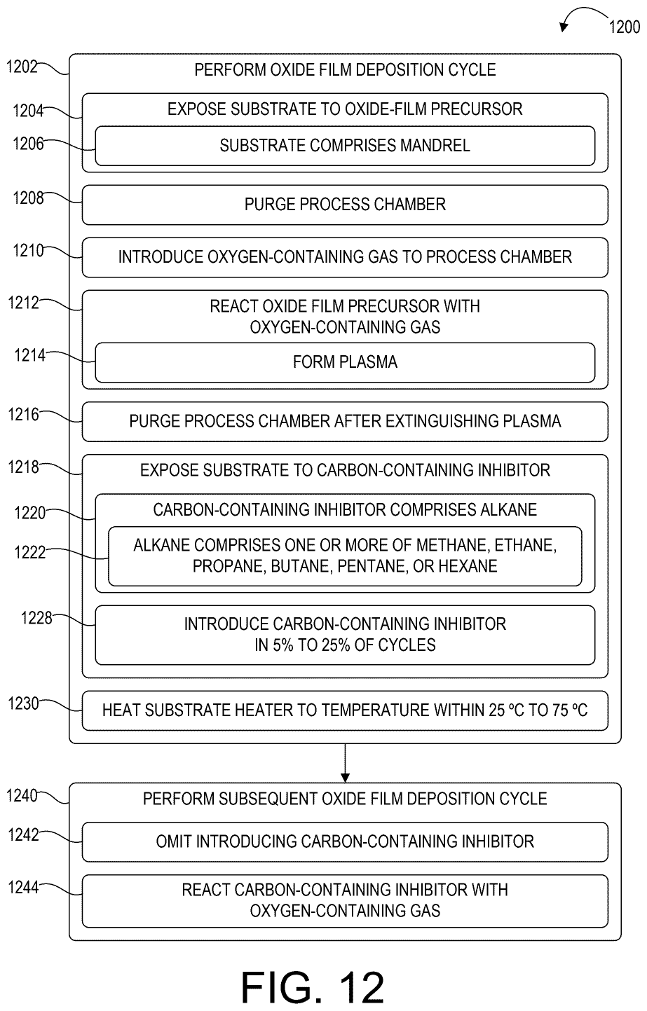

FIG. 12 shows a flow diagram of an example method 1200 for performing atomic layer deposition to grow an oxide film nonconformally. Method 1200 comprises, at 1202, performing at least one oxide film deposition cycle. In some examples, a plurality of oxide film deposition cycles are performed. First deposition cycle 300 and second deposition cycle 400 are examples of oxide film deposition cycles.

At 1204, the oxide deposition cycle 1202 comprises exposing a substrate to an oxide-film precursor. Any suitable oxide-film precursor may be used. For example, when a silicon dioxide film is formed, the oxide-film precursor may comprise polysilanes, siloxanes, aminosilanes, halosilanes, or organosilanes, such as those described in more detail above. Example oxide-film precursors for metal oxide films include HfCl₄, Hf(N(C₂H₅)₂)₄, Hf(OC(CH₃)₃)₄, TCl₄, Ti(OCH(CH₃)₂)₄, WF₆, WCl₆, W(CO)₆, SnCl₄, (CH₃)₄Sn, (C₂H₅)₄Sn, (CH₃)₂SnCl₂, Bu₂Sn(OMe)₂, Sn(NMe₂)₄, Me₂Sn(NMe₂)₂, Me₃Sn(NMe₂), MoCl₅, MoO₂Cl₂, MoOCH₄, and Mo(CO)₆. In some examples, at 1206, the substrate comprises mandrels.

Continuing, at 1208, the oxide deposition cycle 1202 may optionally comprise purging the process chamber. Purging the process chamber may be performed to remove at least some residual oxide-film precursor.

At 1210, the oxide deposition cycle further comprises introducing an oxygen-containing gas. Any suitable oxygen-containing gas may be used, such as oxygen, ozone, or water vapor. The oxide deposition cycle 1202 further comprises, at 1212, reacting the oxide-film precursor with the oxygen-containing gas. In some examples, at 1214, the oxide deposition cycle 1202 comprises forming a plasma comprising the oxygen-containing gas to oxidize the oxide-film precursor, forming an oxide film. In some examples, reactive oxygen-containing species in the plasma oxidize adsorbed carbon-containing inhibitor that was deposited nonconformally in a previous cycle. In some examples, at 1216, the method comprises purging the process chamber after extinguishing the plasma.

In at least some deposition cycles, method 1200 comprises, at 1218, exposing the substrate to a carbon-containing inhibitor. Any suitable carbon-containing inhibitor may be used. In some examples, at 1220, the carbon-containing inhibitor comprises an alkane comprising a general formula CₙH₂ₙ₊₂ in which n=1 to 10. In some examples, at 1222, the alkane comprises one or more of methane, ethane, propane, butane, pentane, or hexane. In some examples, the alkane comprises a substituted linear alkane. In some examples, the carbon-containing inhibitor comprises one or more of an alkene, an alkyne, a cyclic hydrocarbon, an aromatic, an alcohol, a diol, an aldehyde, an ester, an ether, an alkyl halide, an alkyl amine, or an alkyl diamine. In still other examples, the carbon-containing inhibitor may comprise a mixture of carbon-containing inhibitors. Examples of suitable alkenes (CₙH₂ₙ for alkenes with a single carbon-carbon double bond, in which n=2 to 10) may include ethene, propene, and butene. Example of suitable alkynes (CₙH₂ₙ₋₂ for alkynes comprising a single carbon-carbon triple bond, in which n=2 to 10) may include acetylene, propyne, and butyne. Example of suitable cyclic hydrocarbons may include cyclobutene, cyclopentane and cyclohexane. Example of suitable aromatics may include benzene, toluene, pyridine, and pyrimidine. Example of suitable alcohols may include methanol, ethanol, and propanol. Examples of suitable diols may include ethylene glycol, propylene glycol, and hydroquinone. Examples of suitable aldehydes may include formaldehyde and acetaldehyde. Examples of suitable esters may include ethyl formate, methyl acetate, and ethyl acetate. Example of suitable ethers may include diethyl ether, methyl phenyl ether, or aromatic ethers such as furan. Examples of suitable ketones may include acetone and methyl ethyl ketone. Examples of suitable alkyl halides may include ethyl fluoride, isopropyl bromide, and t-butyl chloride. Examples of suitable alkyl amines may include methylamine, dimethylamine, trimethylamine, and piperidine. Examples of suitable alkyl diamines may include ethylenediamine and 1,3-diaminopropane. In some examples, at 1228, the carbon-containing inhibitor is introduced in 5% to 25% of deposition cycles.

In some examples, at 1230, method 1200 further comprises heating a substrate heater to a temperature with a range of 25° C. to 75° C. In some examples, the method comprises heating the substrate heater to a temperature with a range of 25° C. to 650° C.

Method 1200 may further comprise, at 1240, performing a subsequent oxide film deposition cycle. The subsequent oxide film deposition cycle may comprise introducing a carbon-containing inhibitor (e.g., second deposition cycle 400). However, in some examples, at 1242, the subsequent oxide film deposition cycle omits introducing the carbon-containing inhibitor (e.g., first deposition cycle 300). Further, at 1244, the subsequent oxide film deposition cycle comprises reacting carbon-containing inhibitor introduced at 1218 with the oxygen-containing gas.

The examples described herein may provide for the efficient formation of films and/or structures on a substrate with a relatively high degree of control over feature sizes, film thickness, uniformity, and other characteristics. In some examples, throughput for forming a low temperature oxide-type film may be ≥125 substrates per hour per chamber. In some examples, throughput for forming a low temperature hard mask-type film may be ≥90 substrates per hour per chamber. In some examples, a SiO₂ blanket oxide may be formed with chemistry usage that is ≤2.6 mg per cycle. In some examples, a SiO₂ blanket oxide may comprise an accumulation limit ≥3.0 μm. In other examples, a film may have one or more values outside of these example ranges.

In some examples, the methods and processes described herein may be tied to a computing system of one or more computing devices. In particular, such methods and processes may be implemented as a computer-application program or service, an application-programming interface (API), a library, and/or other computer-program product.

FIG. 13 schematically shows a non-limiting example of a computing system 1300 that can enact one or more of the methods and processes described above. Computing system 1300 is shown in simplified form. Computing system 1300 may take the form of one or more personal computers, workstations, computers integrated with substrate processing tools, and/or network accessible server computers.

Computing system 1300 includes a logic machine 1302 and a storage machine 1304. Computing system 1300 may optionally include a display subsystem 1306, input subsystem 1308, communication subsystem 1310, and/or other components not shown in FIG. 13. Controller 130 is an example of computing system 1300.

Logic machine 1302 includes one or more physical devices configured to execute instructions. For example, the logic machine may be configured to execute instructions that are part of one or more applications, services, programs, routines, libraries, objects, components, data structures, or other logical constructs. Such instructions may be implemented to perform a task, implement a data type, transform the state of one or more components, achieve a technical effect, or otherwise arrive at a desired result.

The logic machine may include one or more processors configured to execute software instructions. Additionally or alternatively, the logic machine may include one or more hardware or firmware logic machines configured to execute hardware or firmware instructions. Processors of the logic machine may be single-core or multi-core, and the instructions executed thereon may be configured for sequential, parallel, and/or distributed processing. Individual components of the logic machine optionally may be distributed among two or more separate devices, which may be remotely located and/or configured for coordinated processing. Aspects of the logic machine may be virtualized and executed by remotely accessible, networked computing devices configured in a cloud-computing configuration.

Storage machine 1304 includes one or more physical devices configured to hold instructions 1312 executable by the logic machine to implement the methods and processes described herein. When such methods and processes are implemented, the state of storage machine 1304 may be transformed—e.g., to hold different data.

Storage machine 1304 may include removable and/or built-in devices. Storage machine 1304 may include optical memory (e.g., CD, DVD, HD-DVD, Blu-Ray Disc, etc.), semiconductor memory (e.g., RAM, EPROM, EEPROM, etc.), and/or magnetic memory (e.g., hard-disk drive, floppy-disk drive, tape drive, MRAM, etc.), among others. Storage machine 1304 may include volatile, nonvolatile, dynamic, static, read/write, read-only, random-access, sequential-access, location-addressable, file-addressable, and/or content-addressable devices.

It will be appreciated that storage machine 1304 includes one or more physical devices. However, aspects of the instructions described herein alternatively may be propagated by a communication medium (e.g., an electromagnetic signal, an optical signal, etc.) that is not held by a physical device for a finite duration.

Aspects of logic machine 1302 and storage machine 1304 may be integrated together into one or more hardware-logic components. Such hardware-logic components may include field-programmable gate arrays (FPGAs), program- and application-specific integrated circuits (PASIC/ASICs), program- and application-specific standard products (PSSP/ASSPs), system-on-a-chip (SOC), and complex programmable logic devices (CPLDs), for example.

When included, display subsystem 1306 may be used to present a visual representation of data held by storage machine 1304. This visual representation may take the form of a graphical user interface (GUI). As the herein described methods and processes change the data held by the storage machine, and thus transform the state of the storage machine, the state of display subsystem 1306 may likewise be transformed to visually represent changes in the underlying data. Display subsystem 1306 may include one or more display devices utilizing virtually any type of technology. Such display devices may be combined with logic machine 1302 and/or storage machine 1304 in a shared enclosure, or such display devices may be peripheral display devices.

When included, input subsystem 1308 may comprise or interface with one or more user-input devices such as a keyboard, mouse, or touch screen. In some examples, the input subsystem may comprise or interface with selected natural user input (NUI) componentry. Such componentry may be integrated or peripheral, and the transduction and/or processing of input actions may be handled on- or off-board. Example NUI componentry may include a microphone for speech and/or voice recognition, and an infrared, color, stereoscopic, and/or depth camera for machine vision and/or gesture recognition.

When included, communication subsystem 1310 may be configured to communicatively couple computing system 1300 with one or more other computing devices. Communication subsystem 1310 may include wired and/or wireless communication devices compatible with one or more different communication protocols. As non-limiting examples, the communication subsystem may be configured for communication via a wireless telephone network, or a wired or wireless local- or wide-area network. In some examples, the communication subsystem may allow computing system 1300 to send and/or receive messages to and/or from other devices via a network such as the Internet.

It will be understood that the configurations and/or approaches described herein are exemplary in nature, and that these specific examples or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A method of forming an oxide film on a substrate, the method comprising:
performing a plurality of oxide film deposition cycles, at least one oxide film deposition cycle of the plurality of oxide film deposition cycles comprising
exposing the substrate to an oxide-film precursor to adsorb the oxide-film precursor to the substrate,
exposing the substrate to an oxygen-containing gas,
reacting the oxide-film precursor and the oxygen-containing gas, and
exposing the substrate to a carbon-containing inhibitor.

2. The method of claim 1, wherein the method comprises an atomic layer deposition process.

3. The method of claim 1, wherein a subsequent oxide film deposition cycle of the plurality of oxide film deposition cycles that is performed after the at least one oxide film deposition cycle omits exposing the substrate to the carbon-containing inhibitor.

4. The method of claim 1, wherein reacting the oxide-film precursor and the oxygen-containing gas comprises forming a plasma comprising the oxygen-containing gas.

5. The method of claim 4, further comprising reacting the plasma with carbon-containing inhibitor deposited in a prior oxide film deposition cycle of the plurality of oxide film deposition cycles.

6. The method of claim 1, wherein the substrate comprises a stack of alternating layers of a first material and a second material, wherein a gap is formed in the stack of alternating layers of materials, and wherein the oxide film is deposited in the gap.

7. The method of claim 6, wherein the gap comprises an aspect ratio within a range of 40:1 to 100:1.

8. The method of claim 6, wherein the gap comprises a reentrant structure.

9. The method of claim 1, wherein the carbon-containing inhibitor comprises one or more of an alkane, an alkene, an alkyne, a cyclic hydrocarbon, an aromatic, an alcohol, a diol, an aldehyde, an ester, an ether, a ketone, an alkyl halide, an alkyl amine, or an alkyl diamine.

10. The method of claim 1, wherein the oxide film comprises a silicon oxide film.

11. A processing tool, comprising:
a process chamber;
a radiofrequency power source;
one or more gas inlets into the process chamber;
flow control hardware configured to control gas flow through the one or more gas inlets; and
a controller operatively coupled to the flow control hardware and the radiofrequency power source, the controller configured to fill a gap in a substrate disposed within the process chamber by:
operating the flow control hardware to introduce an oxide-film precursor into the process chamber,
operating the flow control hardware to introduce an oxygen-containing gas into the process chamber,
operating the radiofrequency power source to form a plasma comprising the oxygen-containing gas; and
operating the flow control hardware to introduce a carbon-containing inhibitor into the process chamber after operating the radiofrequency power source to extinguish the plasma.

12. The processing tool of claim 11, wherein the controller is further configured to operate the flow control hardware to purge the process chamber after the controller operates the radiofrequency power source to extinguish the plasma.

13. The processing tool of claim 11, further comprising a carbon-containing inhibitor source.

14. The processing tool of claim 13, wherein the carbon-containing inhibitor source comprises one or more of an alkane, an alkene, an alkyne, a cyclic hydrocarbon, an aromatic, an alcohol, a diol, an aldehyde, an ester, an ether, a ketone, an alkyl halide, an alkyl amine, or an alkyl diamine.

15. The processing tool of claim 11, wherein the controller is configured to operate the flow control hardware and the radiofrequency power source to perform a plurality of oxide film deposition cycles, at least some of the oxide film deposition cycles omitting operating the flow control hardware to introduce the carbon-containing inhibitor.

16. The processing tool of claim 11, wherein the controller is configured control the processing tool to fill a reentrant gap in the substrate.

17. The processing tool of claim 11, further comprising a substrate heater operatively coupled to the controller, and wherein the controller is configured to control heating of the substrate heater to a temperature within a range of 25° C. to 75° C.

18. A computer-readable storage device comprising:
instructions executable by a computing device comprising a processor to control a substrate processing tool to fill a gap in a substrate, the instructions executable to
operate flow control hardware of the substrate processing tool to introduce an oxide-film precursor into a process chamber, thereby exposing the gap to the oxide-film precursor,
operate the flow control hardware to introduce an oxygen-containing gas into the process chamber,
operate a radiofrequency power source to form a plasma comprising the oxygen-containing gas, and
operate the flow control hardware to introduce a carbon-containing inhibitor into the process chamber after extinguishing the plasma, thereby exposing the gap to the carbon-containing inhibitor.

19. The computer-readable storage device of claim 18, wherein the instructions executable to operate the flow control hardware to introduce the carbon-containing inhibitor into the process chamber are executable to control introduction of one or more of an alkane, an alkene, an alkyne, a cyclic hydrocarbon, an aromatic, an alcohol, a diol, an aldehyde, an ester, an ether, a ketone, an alkyl halide, an alkyl amine, or an alkyl diamine into the process chamber.

20. The computer-readable storage device of claim 18, wherein the instructions are further executable to perform an oxide film deposition cycle that omits introducing the carbon-containing inhibitor into the process chamber.
